(19) United States
(12) Patent Application Publication
(10) Pub. No.: US 2026/0084418 A1
(43) Pub. Date: Mar. 26, 2026

(54) LIQUID DISCHARGE APPARATUS AND PRINT HEAD DRIVE CIRCUIT

(71) Applicant: SEIKO EPSON CORPORATION, Tokyo (JP)

(72) Inventors: Tomonori YAMADA, Shiojiri (JP); Toru MATSUYAMA, Matsumoto (JP)

(21) Appl. No.: 19/335,019

(22) Filed: Sep. 22, 2025

(30) Foreign Application Priority Data
Sep. 24, 2024 (JP) 2024-165015

(51) Int. Cl. B41J 2/045; H03F 3/21; H03K 17/60; H10D 10/40; H10D 62/10; H10N 30/20; H10N 30/80

(52) U.S. Cl. CPC B41J 2/0455; B41J 2/04541; B41J 2/04581; B41J 2/04588; H10D 10/40; H10D 62/111; H10N 30/2047; H10N 30/802; H03F 3/21; H03K 17/60

(57) ABSTRACT

A liquid discharge apparatus, in which a first transistor included in an amplification circuit included in a print head drive circuit that includes a first conductor, a second conductor, a third conductor, a first layer that includes a first semiconductor region and a second semiconductor region, a second layer that includes a third semiconductor region, and a third layer that includes a fourth semiconductor region, a fifth semiconductor region, and a sixth semiconductor region, the first layer is disposed above the third conductor, the second layer is disposed above the first layer, the third layer is disposed above the second layer, the first conductor is disposed above the fifth semiconductor region, and the second conductor is disposed above the sixth semiconductor region.

The present application is based on, and claims priority from JP Application Serial Number 2024-165015, filed Sep. 24, 2024, the disclosure of which is hereby incorporated by reference herein in its entirety.

### BACKGROUND

### 1. Technical Field

The present disclosure relates to a liquid discharge apparatus and a print head drive circuit.

### 2. Related Art

A liquid discharge apparatus such as an ink jet printer includes a print head that discharges a liquid, and a print head drive circuit that controls the print head, the print head drive circuit outputs a drive signal that drives a drive element such as a piezoelectric element provided in the print head, and the print head discharges ink by the driving of the drive element. In such a liquid discharge apparatus, an image is formed at a medium by landing the ink discharged from the print head at a desired position on the medium.

For example, JP-A-2015-164779 discloses a liquid discharge apparatus including a head drive circuit that outputs a drive signal and a print head unit that discharges ink in response to the drive signal.

In recent years, in response to a market demand for productivity improvement in liquid discharge apparatuses, improvement in an image formation speed on media is required for the liquid discharge apparatuses. Therefore, print head drive circuits that discharge a liquid are required to output drive signals that enable a large number of drive elements to be driven at a higher frequency. However, the technique described in JP-A-2015-164779 is not satisfactory from the viewpoint of outputting drive signals that enable a large number of drive elements to be driven at a higher frequency, and there is room for improvement.

### SUMMARY

According to an aspect of the present disclosure, there is provided a liquid discharge apparatus including: a print head that discharges a liquid in response to a drive signal; and a print head drive circuit that outputs the drive signal, in which the print head drive circuit includes an amplification circuit that outputs the drive signal amplified by a first transistor and a second transistor, the first transistor includes a first conductor that functions as an emitter electrode, a second conductor that functions as a base electrode, a third conductor that functions as a collector electrode, a first layer that includes a first semiconductor region of a first conductive type having a trench and a second semiconductor region of a second conductive type provided in the trench, a second layer that includes a third semiconductor region of the second conductive type, and a third layer that includes a fourth semiconductor region of the first conductive type, a fifth semiconductor region of the first conductive type, and a sixth semiconductor region of the second conductive type positioned to be separated from the fifth semiconductor region, the first layer is disposed above the third conductor, the second layer is disposed above the first layer, the third layer is disposed above the second layer, the first conductor is disposed above the fifth semiconductor region, and the second conductor is disposed above the sixth semiconductor region.

According to an aspect of the present disclosure, there is provided a print head drive circuit that outputs a drive signal to a print head that discharges a liquid in response to the drive signal, the print head drive circuit including: an amplification circuit that outputs the drive signal amplified by a first transistor and a second transistor, in which the first transistor includes a first conductor that functions as an emitter electrode, a second conductor that functions as a base electrode, a third conductor that functions as a collector electrode, a first layer that includes a first semiconductor region of a first conductive type having a trench and a second semiconductor region of a second conductive type provided in the trench, a second layer that includes a third semiconductor region of the second conductive type, and a third layer that includes a fourth semiconductor region of the first conductive type, a fifth semiconductor region of the first conductive type, and a sixth semiconductor region of the second conductive type positioned to be separated from the fifth semiconductor region, the first layer is disposed above the third conductor, the second layer is disposed above the first layer, the third layer is disposed above the second layer, the first conductor is disposed above the fifth semiconductor region, and the second conductor is disposed above the sixth semiconductor region.

### BRIEF DESCRIPTION OF THE DRAWINGS

FIG. 1 is a diagram illustrating an example of a schematic configuration of a liquid discharge apparatus.

FIG. 2 is a diagram illustrating an example of a functional configuration of the liquid discharge apparatus.

FIG. 3 is a diagram illustrating a schematic structure of a discharge section.

FIG. 4 is a diagram illustrating an example of signal waveforms of drive signals.

FIG. 5 is a diagram illustrating an example of a configuration of a selection control circuit and a selection circuit.

FIG. 6 is a diagram illustrating an example of decoding contents in a decoder.

FIG. 7 is a diagram illustrating an example of a configuration of the selection circuit.

FIG. 8 is a diagram for describing operations of the selection control circuit and the selection circuit.

FIG. 9 is a diagram illustrating an example of a configuration of a drive circuit.

FIG. 10 is a diagram illustrating an example of an operation of an amplification control circuit.

FIG. 11 is a diagram illustrating an example of a structure of a transistor.

FIG. 12 is a diagram illustrating comparison results of an example of a current amplification factor of an npn type bipolar transistor having a structure in the related art and an example of a current amplification factor of the transistor of the present embodiment.

### DESCRIPTION OF EMBODIMENTS

Hereinafter, appropriate embodiments of the present disclosure will be described with reference to the drawings. The drawings to be used are for convenience of description. In addition, embodiments to be described below do not inappropriately limit the contents of the present disclosure described in the claims. Moreover, not all of configurations to be described below are necessarily essential components of the present disclosure.

### 1. Overview of Liquid Discharge Apparatus

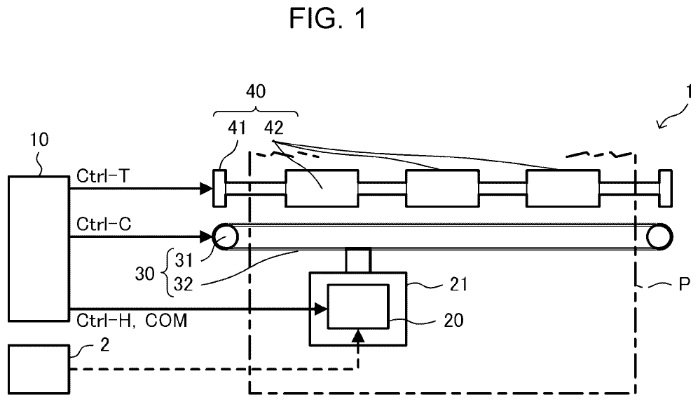

FIG. 1 is a diagram illustrating an example of a schematic configuration of a liquid discharge apparatus 1. The liquid discharge apparatus 1 is a serial printing-type ink jet printer in which a carriage 21 on which a print head 20 that discharges ink as an example of a liquid is mounted reciprocates along a scanning axis and discharges ink to a medium P that is transported along a transport direction to form a desired image on the medium P. As the medium P that is used in such a liquid discharge apparatus 1, any printing target such as a printing paper, a resin film, or a cloth can be used. The liquid discharge apparatus 1 is not limited to the serial printing-type ink jet printer, and may be a line printing-type ink jet printer. In addition, the liquid discharge apparatus 1 is not limited to an ink jet printer, and may be a coloring material discharge apparatus used for manufacturing a color filter such as a liquid crystal display, an electrode material discharge apparatus used for forming an electrode such as an organic EL display or a field emission display (FED), a bioorganic substance discharge apparatus used for manufacturing a biochip, a stereolithography apparatus, a textile printing apparatus, and the like.

As illustrated in FIG. 1, the liquid discharge apparatus 1 includes an ink container 2, a control unit 10, the print head 20, a moving unit 30, and a transport unit 40.

A plurality of types of ink to be discharged to the medium P are stored in the ink container 2. Examples of the colors of the ink stored in the ink container 2 include black, cyan, magenta, yellow, red, and gray. As the ink container 2 in which such ink is stored, an ink cartridge, a bag-shaped ink pack formed of a flexible film, an ink tank into which ink can be replenished, and the like can be used.

The control unit 10 includes, for example, a processing circuit such as a central processing unit (CPU) or a field programmable gate array (FPGA), a storage circuit such as a semiconductor memory, and various other circuits, and controls each element of the liquid discharge apparatus 1 including the print head 20.

The print head 20 is mounted on the carriage 21. In addition, the carriage 21 is fixed to an endless belt 32 that is included in the moving unit 30. In addition to the print head 20, the carriage 21 may be mounted on the ink container 2.

A control signal Ctrl-H for controlling the print head 20 output by the control unit 10 and a drive signal COM are input to the print head 20 mounted on the carriage 21. In addition, the ink stored in the ink container 2 is supplied to the print head 20 via a tube (not illustrated). The print head 20 discharges the ink that is supplied from the ink container 2 based on the input control signal Ctrl-H and drive signal COM.

The moving unit 30 includes a carriage motor 31 and the endless belt 32. The carriage motor 31 is driven based on the control signal Ctrl-C that is input from the control unit 10. The endless belt 32 rotates in accordance with the driving of the carriage motor 31. As a result, the carriage 21 fixed to the endless belt 32 reciprocates along the scanning axis. That is, the print head 20 mounted on the carriage 21 reciprocates along the scanning axis intersecting with the transport direction in which the medium P is transported.

The transport unit 40 includes a transport motor 41 and transport rollers 42. The transport motor 41 is driven based on the control signal Ctrl-T that is input from the control unit 10. The transport rollers 42 rotate in accordance with the driving of the transport motor 41. The medium P is transported in the transport direction in accordance with the rotation of the transport rollers 42.

In the liquid discharge apparatus 1 configured as described above, in conjunction with the transport of the medium P by the transport unit 40 and the reciprocating motion of the carriage 21 by the moving unit 30, the print head 20 mounted on the carriage 21 discharges the ink to the medium P. As a result, the ink that is discharged from the print head 20 lands on any position on the surface of the medium P. As a result, a desired image is formed at the medium P.

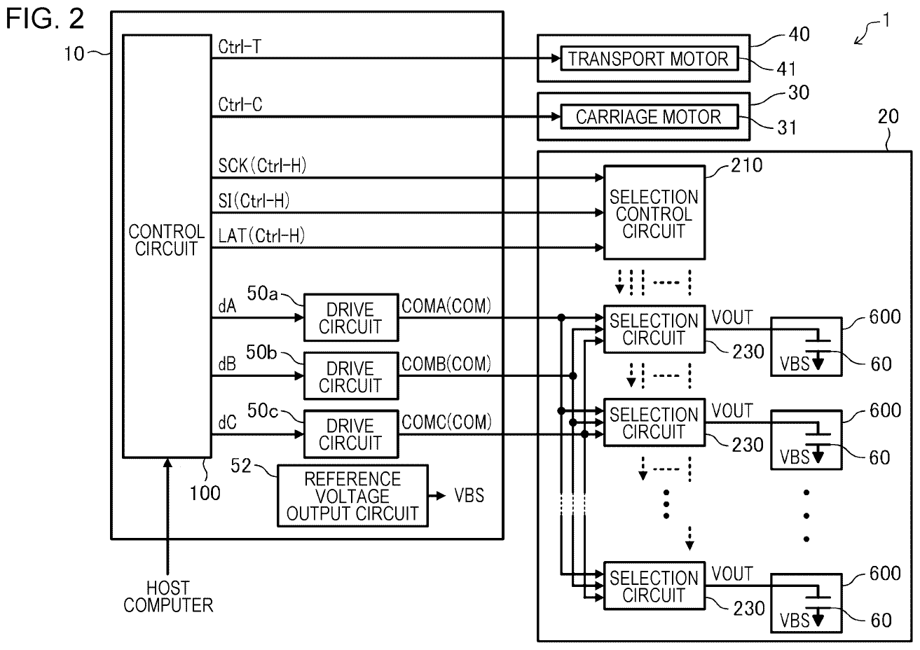

A specific example of the functional configuration of the liquid discharge apparatus 1 configured as described above will be described. FIG. 2 is a diagram illustrating an example of the functional configuration of the liquid discharge apparatus 1. As illustrated in FIG. 2, the liquid discharge apparatus 1 includes the control unit 10, the print head 20, the moving unit 30, and the transport unit 40.

The control unit 10 includes a control circuit 100, drive circuits 50a, 50b, and 50c, and a reference voltage output circuit 52.

When an image signal is input from an external device such as a host computer, the control circuit 100 generates various control signals in response to the image signal and outputs the generated control signals to the corresponding configurations.

Specifically, when an image signal is input, and a printing process is executed on the medium P, the control circuit 100 generates the control signal Ctrl-T and the control signal Ctrl-C. The control signal Ctrl-T output by the control circuit 100 is input to the transport motor 41 included in the transport unit 40. The transport motor 41 is driven according to the control signal Ctrl-T. The medium P is transported along the transport direction by the driving force of the transport motor 41. In addition, the control signal Ctrl-C output by the control circuit 100 is input to the carriage motor 31 included in the moving unit 30. The carriage motor 31 is driven according to the control signal Ctrl-C. The carriage 21 on which the print head 20 is mounted reciprocates along the scanning axis by the driving force of the carriage motor 31. The transport unit 40 may include one or a plurality of transport rotors in addition to the transport motor 41. In addition, the transport unit 40 may include a transport motor driver circuit for converting the control signal Ctrl-T into a predetermined signal for driving the transport motor 41. In addition, the moving unit 30 may include a carriage motor driver circuit for converting the control signal Ctrl-C into a predetermined signal for driving the carriage motor 31.

In addition, the control circuit 100 generates digital basic drive signals dA, dB, and dC and outputs the digital basic drive signals dA, dB, and dC to the corresponding drive circuits 50a, 50b, and 50c.

The basic drive signal dA is input to the drive circuit 50a. The drive circuit 50a performs digital/analog conversion on the input basic drive signal dA and performs AB-class amplification on the converted analog signal, thereby generating a drive signal COMA as the drive signal COM and outputting the drive signal COMA to the print head 20. The basic drive signal dB is input to the drive circuit 50b. The drive circuit 50b performs digital/analog conversion on the input basic drive signal dB and performs AB-class amplification on the converted analog signal, thereby generating a drive signal COMB as the drive signal COM and outputting the drive signal COMB to the print head 20. The basic drive signal dC is input to the drive circuit 50c. The drive circuit 50c performs digital/analog conversion on the input basic drive signal dC and performs AB-class amplification on the converted analog signal, thereby generating a drive signal COMC as the drive signal COM and outputting the drive signal COMC to the print head 20.

That is, the control circuit 100 outputs the basic drive signals dA, dB, and dC that serve as the bases of the drive signals COMA, COMB, and COMC as the drive signal COM, and the drive circuits 50a, 50b, and 50c perform AB-class amplification on the signals having signal waveforms defined by the input basic drive signals dA, dB, and dC, thereby generating the drive signals COMA, COMB, and COMC and outputting the drive signals to the print head 20.

The drive circuits 50a, 50b, and 50c may generate the corresponding drive signals COMA, COMB, and COMC by performing B-class amplification instead of AB-class amplification; however, from the viewpoint of enhancing the waveform accuracy of the output drive signals COMA, COMB, and COMC, it is preferable to use AB-class amplification. In addition, the basic drive signals dA, dB, and dC need only to define the signal waveforms of the drive signals COMA, COMB, and COMC output by the corresponding drive circuits 50a, 50b, and 50c, and may be analog signals.

The reference voltage output circuit 52 generates a reference voltage signal VBS that is a constant DC voltage at a voltage value of 5.5 V, 6 V, or the like, and outputs the reference voltage signal VBS to the print head 20. The reference voltage signal VBS functions as a reference potential for driving a piezoelectric element 60 (to be described below) of the print head 20. The potential of the reference voltage signal VBS is not limited to 5.5 V and 6 V, and may be a ground potential.

In addition, the control circuit 100 generates a clock signal SCK, a print data signal SI, and a latch signal LAT as the control signal Ctrl-H based on the image signal input from the external device, and outputs the generated signals to the print head 20.

The print head 20 includes a selection control circuit 210, a plurality of selection circuits 230, and a plurality of discharge sections 600. The plurality of discharge sections 600 are provided to correspond to the plurality of selection circuits 230, respectively.

The clock signal SCK, the print data signal SI, and the latch signal LAT are input to the selection control circuit 210 as the control signal Ctrl-H. The selection control circuit 210 generates a selection signal S corresponding to each of the plurality of selection circuits 230 based on the input clock signal SCK, print data signal SI, and latch signal LAT, and outputs the selection signal S to the corresponding selection circuit 230.

The drive signals COMA, COMB, and COMC as the drive signal COM and the corresponding selection signals S output by the selection control circuit 210 are input to each selection circuit 230. The selection circuit 230 selects or deselects each of the drive signals COMA, COMB, and COMC based on the input selection signal S, thereby generating a drive signal VOUT and supplying the generated drive signal VOUT to the corresponding discharge section 600.

Each of the plurality of discharge sections 600 includes the piezoelectric element 60. The drive signal VOUT output by the corresponding selection circuit 230 is supplied to one end of the piezoelectric element 60 included in each of the plurality of discharge sections 600. In addition, the reference voltage signal VBS output by the reference voltage output circuit 52 is commonly supplied to the other end of the piezoelectric element 60 included in each of the plurality of discharge sections 600. In addition, the piezoelectric element 60 is driven according to a potential difference between the drive signal VOUT supplied to one end and the reference voltage signal VBS supplied to the other end. The ink is discharged from the discharge section 600 in an amount corresponding to the driving of the piezoelectric element 60.

As described above, the liquid discharge apparatus 1 of the present embodiment includes the print head 20 that discharges the ink according to the drive signals COMA, COMB, and COMC, and the control unit 10 including the drive circuits 50a, 50b, and 50c that output the drive signal COM. In other words, the drive circuits 50a, 50b, and 50c included in the control unit 10 output the drive signals COMA, COMB, and COMC to the print head 20 that discharges the ink according to the drive signals COMA, COMB, and COMC.

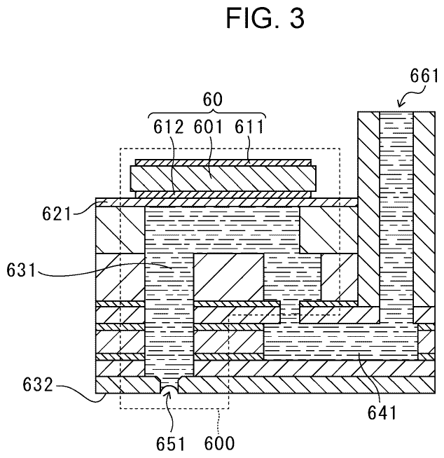

Here, an example of the structure of the discharge section 600 included in the print head 20 will be described. FIG. 3 is a diagram illustrating a schematic structure of one of the plurality of discharge sections 600 included in the print head 20. As illustrated in FIG. 3, the discharge section 600 includes the piezoelectric element 60, a vibrating plate 621, a cavity 631, and a nozzle 651.

The cavity 631 is filled with the ink supplied from a reservoir 641. In addition, the ink is introduced into the reservoir 641 from the ink container 2 via an ink tube (not illustrated) and a supply port 661. That is, the cavity 631 is filled with the ink that is stored in the corresponding ink container 2.

The vibrating plate 621 is displaced by the driving of the piezoelectric element 60 provided on the upper surface in FIG. 3. In addition, the internal volume of the cavity 631 filled with the ink is expanded and reduced in association with the displacement of the vibrating plate 621. That is, the vibrating plate 621 functions as a diaphragm that changes the internal volume of the cavity 631.

The nozzle 651 is an opening which is provided on a nozzle plate 632 and communicates with the cavity 631. When the internal volume of the cavity 631 changes, the ink is discharged from the nozzle 651 in an amount corresponding to the change in internal volume.

The piezoelectric element 60 has a structure in which a piezoelectric body 601 is interposed between a pair of electrodes 611 and 612. In the piezoelectric body 601 having such a structure, the central portions of the electrodes 611 and 612 bend in the vertical direction together with the vibrating plate 621 according to the potential difference of the signals supplied to the electrodes 611 and 612.

For example, the drive signal VOUT is supplied to one end of the piezoelectric element 60 and one of the electrode 611 or the electrode 612, and the reference voltage signal VBS is supplied to the other end of the piezoelectric element 60 and the other of the electrode 611 or the electrode 612. When the voltage value of the drive signal VOUT becomes high, the piezoelectric element 60 bends in the upward direction. In addition, the piezoelectric element 60 bends in the upward direction, whereby the vibrating plate 621 is displaced, and the internal volume of the cavity 631 is expanded. As a result, the ink is drawn from the reservoir 641. On the other hand, when the voltage value of the drive signal VOUT becomes low, the piezoelectric element 60 bends in the downward direction. In addition, the piezoelectric element 60 bends in the downward direction, whereby the vibrating plate 621 is displaced, and the internal volume of the cavity 631 is reduced. As a result, the ink is discharged from the nozzle 651 in an amount corresponding to the degree of reduction.

That is, the discharge section 600 includes the piezoelectric element 60 that is driven by the drive signal VOUT based on the drive signal COM, and discharges the ink by the driving of the piezoelectric element 60. In other words, the print head 20 discharges the ink in response to the drive signals COMA, COMB, and COMC.

Here, in the liquid discharge apparatus 1 of the present embodiment, from the viewpoint of improving the image formation speed on the medium P, that is, improving the productivity in the liquid discharge apparatus 1, a case where the print head 20 has 3,000 or more discharge sections 600 and the drive circuits 50a, 50b, and 50c supply the drive signals COMA, COMB, and COMC to 3,000 or more discharge sections 600 is assumed. That is, a case where the print head 20 has 3,000 or more piezoelectric elements 60 and the drive circuits 50a, 50b, and 50c supply the drive signals COMA, COMB, and COMC to 3,000 or more piezoelectric elements 60 is assumed. As a result, the number of dots that can be formed at the medium P at once, which is the amount of the ink that can be discharged at once, increases, and improvement in the image formation speed on the medium P, that is, improvement in the productivity in the liquid discharge apparatus 1, can be achieved. In other words, in the liquid discharge apparatus 1 of the present embodiment, the print head 20 includes 3000 or more piezoelectric elements 60, and the 3000 or more piezoelectric elements 60 are driven by the drive signals COMA, COMB, and COMC output by the drive circuits 50a, 50b, and 50c included in the control unit 10.

The structure of the piezoelectric element 60 is not limited to one example illustrated in FIG. 3, and may be a structure in which the ink can be discharged from the discharge section 600. Therefore, the structure of the piezoelectric element 60 is not limited to the above-described bending vibration structure, and may be, for example, a structure in which longitudinal vibration is used. In addition, the piezoelectric element 60 may be configured to bend in the downward direction when the voltage value of the drive signal VOUT becomes high and to bend in the upward direction when the voltage value of the drive signal VOUT becomes low.

### 2. Signal Waveform of Drive Signal

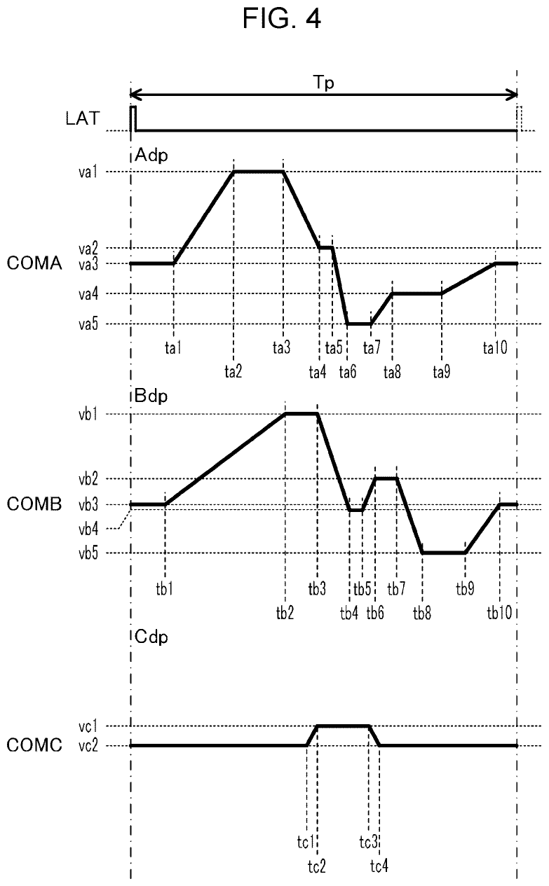

Next, an example of the signal waveform of each of the drive signals COMA, COMB, and COMC output by the drive circuits 50a, 50b, and 50c will be described. FIG. 4 is a diagram illustrating an example of the signal waveforms of the drive signals COMA, COMB, and COMC. As illustrated in FIG. 4, the drive signals COMA, COMB, and COMC include drive waveforms Adp, Bdp, and Cdp disposed in a period tp from the rise of the latch signal LAT to the next rise of the latch signal LAT, respectively. In addition, the selection control circuit 210 and the selection circuit 230 select any of the drive signals COMA, COMB, and COMC, which is any of the drive waveforms Adp, Bdp, and Cdp, based on the clock signal SCK and the print data signal SI every period tp, and output the selected drive signal as the drive signal VOUT.

As illustrated in FIG. 4, in the drive waveform Adp, the voltage value changes between a voltage va1 and a voltage va5 during the period tp, whereby the corresponding piezoelectric element 60 is driven. A predetermined amount of the ink is discharged from the corresponding nozzle 651 by the driving of the piezoelectric element 60. That is, the drive waveform Adp included in the drive signal COMA is a signal waveform for driving the corresponding piezoelectric element 60 such that a predetermined amount of the ink is discharged from the discharge section 600. Here, in the following description, it is assumed that the voltage va1 is 36 V, the voltage va2 is 15 V, the voltage va3 is 12 V, the voltage va4 is 8 V, and the voltage va5 is 5 V, but the values of the voltage va1 to the voltage va5 are not limited thereto.

Specifically, at the timing of the rise of the latch signal LAT and the timing of the start of the period tp, the voltage value of the drive waveform Adp is constant at the voltage va3. Thereafter, the voltage value of the drive waveform Adp starts to increase at a time ta1 and becomes constant at the voltage va1 at a time ta2. In addition, the voltage value of the drive waveform Adp starts to decrease at a time ta3, becomes constant at the voltage va2 at a time ta4, then, starts to decrease again at a time ta5, and becomes constant at the voltage va5 at a time ta6. Thereafter, the voltage value of the drive waveform Adp starts to increase at a time ta7, becomes constant at the voltage va4 at a time ta8, then, starts to increase again at a time ta9, and becomes constant at the voltage va3 at a time ta10. Thereafter, the latch signal LAT rises, whereby the period tp ends.

In the discharge section 600 to which the drive waveform Adp as described above is supplied, the ink that is stored in the ink container 2 is supplied to the cavity 631 via the supply port 661 at the timing of the rise of the latch signal LAT. At this time, the position of the tip portion of the ink stored inside the nozzle 651 included in the discharge section 600, which is the position of a meniscus in the nozzle 651, is substantially the same as the position of the tip of the nozzle 651. In addition, when the voltage value of the drive waveform Adp increases at the time ta1, in the discharge section 600 to which the drive waveform Adp is supplied, the piezoelectric element 60 bends in the upward direction illustrated in FIG. 3, and the internal volume of the cavity 631 increases. As a result, the ink stored inside the nozzle 651 included in the discharge section 600 is drawn into the cavity 631, and the position of the meniscus in the nozzle 651 moves in the upward direction illustrated in FIG. 3.

Thereafter, at the time ta2, the voltage value of the drive waveform Adp becomes constant, whereby the position of the meniscus in the nozzle 651 included in the discharge section 600 is maintained, and then, at the time ta3, when the voltage value of the drive waveform Adp decreases, in the discharge section 600 to which the drive waveform Adp is supplied, the piezoelectric element 60 bends in the downward direction illustrated in FIG. 3 and the internal volume of the cavity 631 decreases. As a result, the ink stored in the cavity 631 is pressurized and moves toward the corresponding nozzle 651. At this time, the central portion of the meniscus formed by the ink stored inside the nozzle 651 is pushed out, and a liquid column stretching downward as illustrated in FIG. 3 is formed.

At the time ta4, when the voltage value of the drive waveform Adp becomes constant, the liquid column formed at the central portion of the meniscus tends to stretch in the downward direction illustrated in FIG. 3 by the inertial force. In addition, at the time ta5, the voltage value of the drive waveform Adp decreases, and the internal volume of the cavity 631 decreases, whereby the ink stored in the cavity 631 is pressurized. As a result, the ink is separated from the liquid column and is discharged as droplets.

Thereafter, at the time ta6, the voltage value of the drive waveform Adp becomes constant, and at the time ta7 to the time ta10, the voltage value of the drive waveform Adp increases and becomes constant at the voltage va3. As a result, the displacement of the piezoelectric element 60 included in the discharge section 600 to which the drive waveform Adp is supplied and the internal volume of the cavity 631 fall into the state where the latch signal LAT rises. At this time, an amount of ink corresponding to the amount of the discharged ink is supplied from the ink container 2 to the cavity 631 via the supply port 661 by the capillary phenomenon. As a result, the position of the meniscus in the nozzle 651 of the discharge section 600 at the timing of the rise of the latch signal LAT becomes a position substantially the same as the position of the tip of the nozzle 651.

In addition, as illustrated in FIG. 4, in the drive waveform Bdp, the voltage value changes between a voltage vb1 and a voltage vb5 during the period tp, whereby the corresponding piezoelectric element 60 is driven. The ink is discharged from the corresponding nozzle 651 in an amount smaller than the above-described predetermined amount by the driving of the piezoelectric element 60. That is, the drive waveform Bdp included in the drive signal COMB is a signal waveform for driving the corresponding piezoelectric element 60 such that the ink is discharged from the discharge section 600 in an amount smaller than the above-described predetermined amount. Here, in the following description, it is assumed that the voltage vb1 is 36 V, the voltage vb2 is 20 V, the voltage vb3 is 12 V, the voltage vb4 is 10 V, and the voltage vb5 is 7 V, but the values of the voltage vb1 to the voltage vb5 are not limited thereto.

Specifically, at the timing of the rise of the latch signal LAT and the timing of the start of the period tp, the voltage value of the drive waveform Bdp is constant at the voltage vb3. Thereafter, the voltage value of the drive waveform Bdp starts to increase at a time tb1 and becomes constant at the voltage vb1 at a time tb2. In addition, the voltage value of the drive waveform Bdp starts to decrease at a time tb3, becomes constant at the voltage vb4 at a time tb4, then, starts to increase at a time tb5, becomes constant at the voltage vb2 at a time tb6, then, starts to decrease at a time tb7, and becomes constant at the voltage vb5 at a time tb8. In addition, the voltage value of the drive waveform Bdp starts to increase at a time tb9 and becomes constant at the voltage vb3 at a time tb10. Thereafter, the latch signal LAT rises, whereby the period tp ends.

In the discharge section 600 to which the drive waveform Bdp as described above is supplied, the ink that is stored in the ink container 2 is supplied to the cavity 631 via the supply port 661 at the timing of the rise of the latch signal LAT. At this time, the position of the tip portion of the ink stored inside the nozzle 651 included in the discharge section 600, which is the position of a meniscus in the nozzle 651, is substantially the same as the position of the tip of the nozzle 651. In addition, when the voltage value of the drive waveform Bdp increases at the time tb1, in the discharge section 600 to which the drive waveform Bdp is supplied, the piezoelectric element 60 bends in the upward direction illustrated in FIG. 3, and the internal volume of the cavity 631 increases. As a result, the ink stored inside the nozzle 651 included in the discharge section 600 is drawn into the cavity 631, and the position of the meniscus in the nozzle 651 moves in the upward direction illustrated in FIG. 3.

Thereafter, at the time tb2, the voltage value of the drive waveform Bdp becomes constant, whereby the position of the meniscus in the nozzle 651 included in the discharge section 600 is maintained, and then, at the time tb3, when the voltage value of the drive waveform Bdp decreases, in the discharge section 600 to which the drive waveform Bdp is supplied, the piezoelectric element 60 bends in the downward direction illustrated in FIG. 3 and the internal volume of the cavity 631 decreases. As a result, the ink stored in the cavity 631 is pressurized and moves toward the corresponding nozzle 651. At this time, the central portion of the meniscus formed by the ink stored inside the nozzle 651 is pushed out, and a liquid column stretching downward as illustrated in FIG. 3 is formed.

At the time tb4, when the voltage value of the drive waveform Bdp becomes constant, the liquid column formed at the central portion of the meniscus tends to stretch in the downward direction illustrated in FIG. 3 by the inertial force. In addition, at the time tb5, when the voltage value of the drive waveform Bdp increases, and the internal volume of the cavity 631 increases, the liquid column that tends to stretch in the downward direction illustrated in FIG. 3 is drawn by the inertial force. At the time tb6 thereafter, the voltage value of the drive waveform Bdp becomes constant, and the voltage value of the drive waveform Bdp then decreases at the time tb7, whereby the internal volume of the cavity 631 decreases, the ink stored in the cavity 631 is pressurized, and the ink is separated from the liquid column, and is discharged as droplets. At this time, at the time tb5, the liquid column that tends to stretch in the downward direction illustrated in FIG. 3 is drawn by the inertial force, and the droplets from which the ink pressurized and separated from the liquid column is separated is discharged at the time tb7, whereby the discharge amount of the ink that is discharged from the discharge section 600 to which the drive waveform Bdp is supplied becomes smaller than the discharge amount of the ink that is discharged from the discharge section 600 to which the drive waveform Adp is supplied.

Thereafter, at the time tb8, the voltage value of the drive waveform Bdp becomes constant, and at the times tb9 and tb10, the voltage value of the drive waveform Bdp increases and becomes constant at the voltage vb3. As a result, the displacement of the piezoelectric element 60 included in the discharge section 600 to which the drive waveform Bdp is supplied and the internal volume of the cavity 631 fall into the state where the latch signal LAT rises. At this time, an amount of ink corresponding to the amount of the discharged ink is supplied from the ink container 2 to the cavity 631 via the supply port 661 by the capillary phenomenon. As a result, the position of the meniscus in the nozzle 651 of the discharge section 600 at the timing of the rise of the latch signal LAT becomes a position substantially the same as the position of the tip of the nozzle 651.

In addition, as illustrated in FIG. 4, in the drive waveform Cdp, the voltage value changes between a voltage vc1 and a voltage vc2 during the period tp, whereby the corresponding piezoelectric element 60 is driven. The ink is not discharged from the corresponding nozzle 651 by the driving of the piezoelectric element 60, and the ink in the vicinity of the opening portion of the nozzle 651 vibrates. As a result, a possibility of an increase in the viscosity of the ink in the vicinity of the opening portion of the nozzle 651 is reduced. That is, the drive waveform Cdp included in the drive signal COMC is a signal waveform for driving the piezoelectric element 60 such that the ink is not discharged from the discharge section 600, and the ink in the vicinity of the opening portion of the nozzle 651 included in the discharge section 600 vibrates. Here, in the following description, it is assumed that the voltage vc1 is 15 V, and the voltage vc2 is 12 V, but the values of the voltage vc1 and the voltage vc2 are not limited thereto.

Specifically, at the timing of the rise of the latch signal LAT and the timing of the start of the period tp, the voltage value of the drive waveform Cdp is constant at the voltage vc2. Thereafter, the voltage value of the drive waveform Cdp starts to increase at a time tc1 and becomes constant at the voltage vc1 at a time tc2. In addition, the voltage value of the drive waveform Cdp starts to decrease at a time tc3 and becomes constant at the voltage vc2 at a time tc4. Thereafter, the latch signal LAT rises, whereby the period tp ends.

In the discharge section 600 to which the drive waveform Cdp as described above is supplied, the ink that is stored in the ink container 2 is supplied to the cavity 631 via the supply port 661 at the timing of the rise of the latch signal LAT. At this time, the position of the tip portion of the ink stored inside the nozzle 651 included in the discharge section 600, which is the position of a meniscus in the nozzle 651, is substantially the same as the position of the tip of the nozzle 651. In addition, when the voltage value of the drive waveform Cdp increases at the time tc1, in the discharge section 600 to which the drive waveform Cdp is supplied, the piezoelectric element 60 bends in the upward direction illustrated in FIG. 3, and the internal volume of the cavity 631 increases. As a result, the ink stored inside the nozzle 651 included in the discharge section 600 is drawn into the cavity 631, and the position of the meniscus in the nozzle 651 moves in the upward direction illustrated in FIG. 3. Thereafter, at the time tc2, the voltage value of the drive waveform Bdp becomes constant, whereby the position of the meniscus in the nozzle 651 included in the discharge section 600 is maintained, and then, at the time tc3, when the voltage value of the drive waveform Cdp decreases, in the discharge section 600 to which the drive waveform Cdp is supplied, the piezoelectric element 60 bends in the downward direction illustrated in FIG. 3 and the internal volume of the cavity 631 decreases. As a result, the ink stored in the cavity 631 is pressurized and moves toward the corresponding nozzle 651. At this time, the central portion of the meniscus formed by the ink stored inside the nozzle 651 is pushed out, and a liquid column stretching downward as illustrated in FIG. 3 is formed. Thereafter, at the time tc4, the voltage value of the drive waveform Cdp becomes constant. At this time, the change in the voltage value of the drive waveform Cdp is smaller than the change in the voltage value of the drive waveform Adp and the change in the voltage value of the drive waveform Bdp, and the ink is thus not separated from the liquid column. Therefore, the ink simply vibrates from the nozzle 651 but is not discharged.

In addition, at the time tc4, the voltage value of the drive waveform Cdp is constant at the voltage vc2, whereby the displacement of the piezoelectric element 60 included in the discharge section 600 to which the drive waveform Cdp is supplied and the internal volume of the cavity 631 fall into the state where the latch signal LAT rises.

As described above, the drive circuit 50a outputs the drive signal COMA including the drive waveform Adp that drives the piezoelectric element 60 such that a predetermined amount of the ink is discharged from the discharge section 600, the drive circuit 50b outputs the drive signal COMB including the drive waveform Bdp that drives the piezoelectric element 60 such that the ink is discharged from the discharge section 600 in an amount smaller than the predetermined amount, and the drive circuit 50c outputs the drive signal COMC including the drive waveform Cdp that drives the piezoelectric element 60 such that the ink is not discharged from the discharge section 600 and the ink in the vicinity of the opening portion of the corresponding nozzle 651 vibrates. In the following description, when the drive waveform Adp is supplied to one end of the piezoelectric element 60, the amount of the ink discharged from the corresponding discharge section 600 may be referred to as a large amount, and when the drive waveform Bdp is supplied to one end of the piezoelectric element 60, the amount of the ink discharged from the corresponding discharge section 600 may be referred to as a small amount. In addition, when the drive waveform Cdp is supplied to one end of the piezoelectric element 60, the operation of vibrating the ink in the vicinity of the nozzle opening portion of the discharge section 600 corresponding to the piezoelectric element 60 may be referred to as micro-vibration.

Here, in the liquid discharge apparatus 1 of the present embodiment, from the viewpoint of improving the image formation speed on the medium P, that is, improving the productivity in the liquid discharge apparatus 1, a case where the period tp in which the ink is discharged from the discharge section 600 by the drive signals COMA, COMB, and COMC is 10 μs or shorter is assumed. That is, a case where the frequencies of the drive signals COMA, COMB, and COMC output by the drive circuits 50a, 50b, and 50c and the frequency of the period tp are 100 kHz or higher is assumed. As a result, in the liquid discharge apparatus 1 of the present embodiment, improvement in the image formation speed on the medium P, that is, improvement in the productivity in the liquid discharge apparatus 1, can be achieved. That is, the frequencies of the drive signals COMA, COMB, and COMC are 100 kHz or higher.

### 3. Configuration and Operation of Selection Control Circuit and Selection Circuit

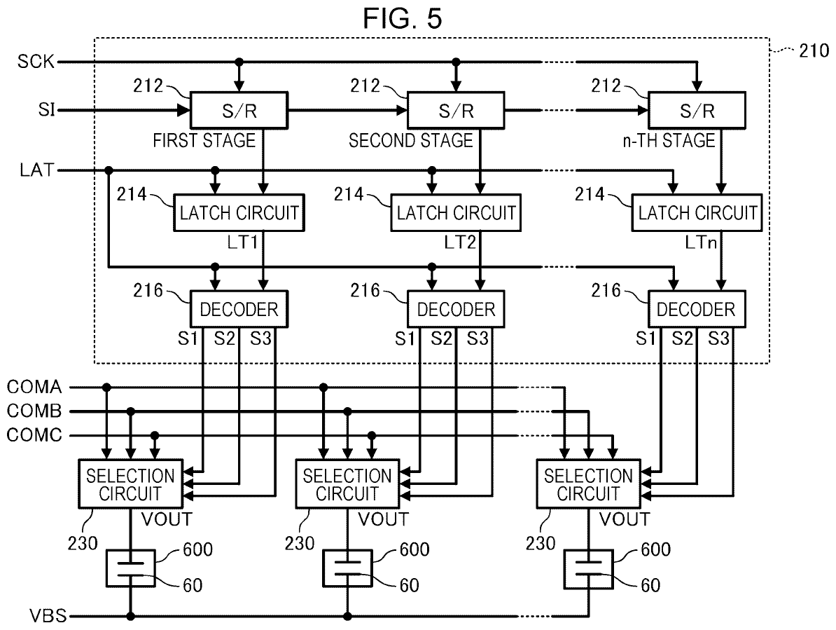

Next, the configurations and operations of the selection control circuit 210 and the selection circuit 230 that select or deselect the signal waveforms included in the drive signals COMA, COMB, and COMC, thereby generating the drive signal VOUT and outputting the generated drive signal VOUT to the corresponding discharge section 600 will be described. FIG. 5 is a diagram illustrating an example of the configuration of the selection control circuit 210 and the selection circuit 230. In the following description, the 3000 piezoelectric elements 60 included in the print head 20 will be generalized, and will be described as n piezoelectric elements 60.

The clock signal SCK, the print data signal SI, and the latch signal LAT are input to the selection control circuit 210. In addition, in the selection control circuit 210, a set of a shift register (S/R) 212, a latch circuit 214, and a decoder 216 is provided corresponding to each of the n piezoelectric elements 60. That is, the selection control circuit 210 includes n shift registers 212, n latch circuits 214, and n decoders 216.

The print data signal SI is input to the selection control circuit 210 in synchronization with the clock signal SCK. In addition, the print data signal SI correspondingly includes 2-bit print data [SIH, SIL] for selecting any of “large dot LD,” “small dot SD,” “non-recording ND,” and “micro-vibration BSD” in each of the n piezoelectric elements 60 in series. The print data [SIH, SIL] included in the print data signal SI is held in the n shift registers 212 that correspond to the n piezoelectric elements 60. Specifically, the n shift registers 212 corresponding to the piezoelectric element 60 are coupled in cascade to each other, and the serially input print data signal SI is sequentially transferred to the subsequent shift register 212 according to the clock signal SCK. In addition, when the print data [SIH, SIL] is held in the corresponding shift register 212, the clock signal SCK is stopped. As a result, the print data [SIH, SIL] included in the print data signal SI is held in the corresponding shift registers 212. In FIG. 5, in order to distinguish the n shift registers 212 from each other, the shift registers 212 are denoted as a first stage, a second stage, . . . , n-th stage in order from the upstream to which the print data signal SI is input.

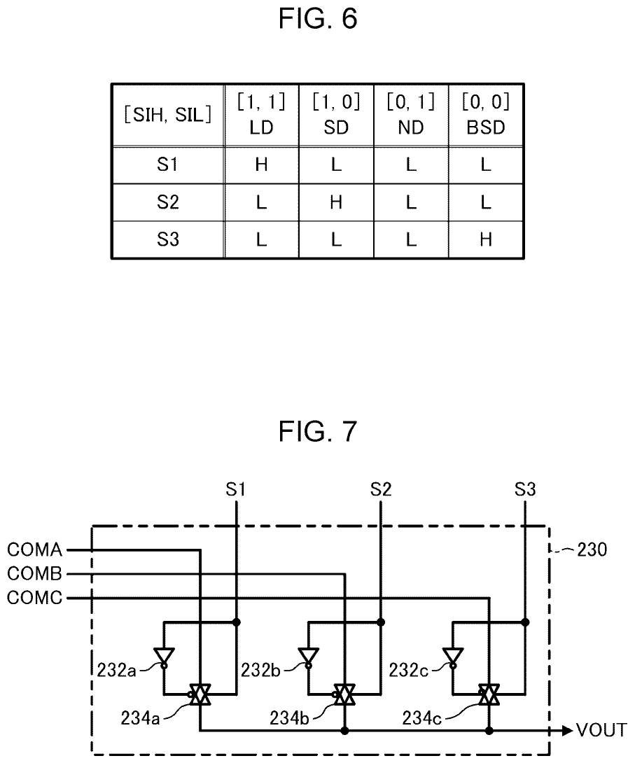

Each of the n latch circuits 214 latches the print data [SIH, SIL] held in the corresponding shift register 212 all at once at the rise of the latch signal LAT. The print data [SIH, SIL] latched by the latch circuit 214 is input to the corresponding decoder 216. FIG. 6 is a diagram illustrating an example of decoding contents in the decoder 216. The decoder 216 outputs selection signals S1, S2, and S3 as the selection signal S of a logic level that is defined by the input print data [SIH, SIL] in the period tp. For example, when the print data [SIH, SIL]=[1, 0] is input to the decoder 216, the decoder 216 outputs an L level selection signal S1, an H level selection signal S2, and an L level selection signal S3 in the period tp.

The selection signals S1, S2, and S3 output by the decoder 216 are input to the selection circuit 230. The selection circuit 230 is provided corresponding to each of the n discharge sections 600. FIG. 7 is a diagram illustrating an example of the configuration of the selection circuit 230. As illustrated in FIG. 7, the selection circuit 230 includes inverters 232a, 232b, and 232c which are NOT circuits, and transfer gates 234a, 234b, and 234c.

The selection signal S1 is input to a positive control end, which is not marked with a circle, at the transfer gate 234a, and after the logic level thereof is inverted by the inverter 232a, the selection signal S1 is input to a negative control end marked with a circle at the transfer gate 234a. The drive signal COMA is supplied to the input end of the transfer gate 234a. When the selection signal S1 at the high level is input, the transfer gate 234a is made conductive between the input end and the output end, and when the selection signal S1 at the low level is input, the transfer gate 234a is made non-conductive between the input end and the output end. That is, the transfer gate 234a outputs the drive waveform Adp included in the drive signal COMA from the output end when the logic level of the selection signal S1 is a high level, and does not output the drive waveform Adp included in the drive signal COMA from the output end when the logic level of the selection signal S1 is a low level.

The selection signal S2 is input to a positive control end, which is not marked with a circle, at the transfer gate 234b, and after the logic level thereof is inverted by the inverter 232b, the selection signal S2 is input to a negative control end marked with a circle at the transfer gate 234b. The drive signal COMB is supplied to the input end of the transfer gate 234b. When the selection signal S2 at the high level is input, the transfer gate 234b is made conductive between the input end and the output end, and when the selection signal S2 at the low level is input, the transfer gate 234b is made non-conductive between the input end and the output end. That is, the transfer gate 234b outputs the drive waveform Bdp included in the drive signal COMB from the output end when the logic level of the selection signal S2 is a high level, and does not output the drive waveform Bdp included in the drive signal COMB from the output end when the logic level of the selection signal S2 is a low level.

The selection signal S3 is input to a positive control end, which is not marked with a circle, at the transfer gate 234c, and after the logic level thereof is inverted by the inverter 232c, the selection signal S3 is input to a negative control end marked with a circle at the transfer gate 234c. In addition, the drive signal COMC is supplied to the input end of the transfer gate 234c. When the selection signal S3 at the high level is input, the transfer gate 234c is made conductive between the input end and the output end, and when the selection signal S3 at the low level is input, the transfer gate 234c is made non-conductive between the input end and the output end. That is, the transfer gate 234c outputs the drive waveform Cdp included in the drive signal COMC from the output end when the logic level of the selection signal S3 is a high level, and does not output the drive waveform Cdp included in the drive signal COMC from the output end when the logic level of the selection signal S3 is a low level.

In addition, in the selection circuit 230, the output end of the transfer gate 234a, the output end of the transfer gate 234b, and the output end of the transfer gate 234c are commonly coupled to each other. A signal at the coupling point where the output end of the transfer gate 234a, the output end of the transfer gate 234b, and the output end of the transfer gate 234c are commonly coupled is output as the drive signal VOUT.

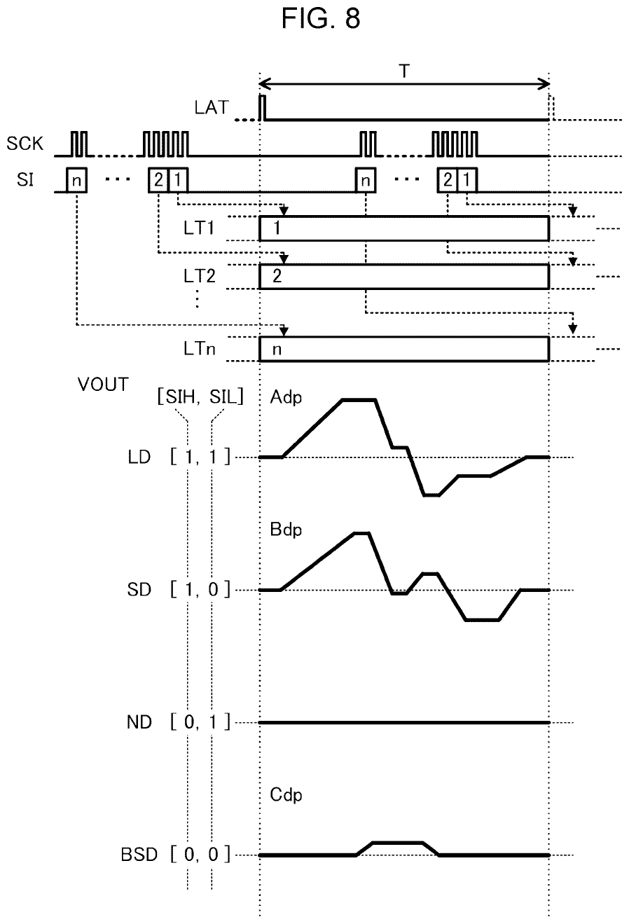

Here, the operations of the selection control circuit 210 and the selection circuit 230 will be described using FIG. 8. FIG. 8 is a diagram for describing operations of the selection control circuit 210 and the selection circuit 230. The print data signal SI is input to the selection control circuit 210 as a serial signal synchronized with the clock signal SCK, and is sequentially transferred to the n shift registers 212 corresponding to the n piezoelectric elements 60 in synchronization with the clock signal SCK. Thereafter, when the input of the clock signal SCK is stopped, the print data [SIH, SIL] that corresponds to each of the n piezoelectric elements 60 is held in the shift registers 212. The print data signal SI is input in the order corresponding to the n-th stage, . . . , the second stage, and the first stage piezoelectric elements 60 of the shift register 212.

In addition, when the latch signal LAT rises, each of the latch circuits 214 latches the print data [SIH, SIL] held in the shift register 212 all at once. LT1, LT2, . . . , LTn illustrated in FIG. 8 represent the print data [SIH, SIL] latched by the latch circuits 214 corresponding to the shift registers 212 of the first stage, the second stage, . . . , the n-th stage.

The decoder 216 outputs the selection signals S1, S2, and S3 of the logic level defined by the latched print data [SIH, SIL] every period tp. The selection circuit 230 selects or deselects the drive signals COMA, COMB, and COMC according to the logic levels of the selection signals S1, S2, and S3 output by the decoder 216, thereby generating the drive signal VOUT.

Specifically, when the print data [SIH, SIL]=[1, 1] is input to the decoder 216, the decoder 216 sets the logic levels of the selection signals S1, S2, and S3 in the period tp to H, L, and L levels. As a result, the selection circuit 230 supplies the drive signal VOUT including the drive waveform Adp to the piezoelectric element 60 included in the corresponding discharge section 600 in the period tp. As a result, a large amount of the ink is discharged from the corresponding discharge section 600. The large amount of the ink discharged from the discharge section 600 lands on the medium P, whereby the large dot LD is formed at the medium P.

In addition, when the print data [SIH, SIL]=[1, 0] is input to the decoder 216, the decoder 216 sets the logic levels of the selection signals S1, S2, and S3 in the period tp to L, H, and L levels. As a result, the selection circuit 230 supplies the drive signal VOUT including the drive waveform Bdp to the piezoelectric element 60 included in the corresponding discharge section 600 in the period tp. As a result, a small amount of the ink is discharged from the corresponding discharge section 600. The small amount of the ink discharged from the discharge section 600 lands on the medium P, whereby the small dot SD is formed at the medium P.

In addition, when the print data [SIH, SIL]=[0, 1] is input to the decoder 216, the decoder 216 sets the logic levels of the selection signals S1, S2, and S3 in the period tp to L, L, and L levels. As a result, the selection circuit 230 deselects any of the drive waveforms Adp, Bdp, and Cdp in the period tp. At this time, a signal having a constant voltage value that is held by the capacitance component of the piezoelectric element 60 is supplied to the piezoelectric element 60 included in the corresponding discharge section 600. That is, the selection circuit 230 supplies the drive signal VOUT having a constant voltage value to the piezoelectric element 60 included in the corresponding discharge section 600 in the period tp. As a result, the piezoelectric element 60 included in the corresponding discharge section 600 is not driven, and the ink is not discharged from the discharge section 600. Therefore, the ink does not land on the medium P, and the non-recording ND that does not form dots on the medium P is executed.

In addition, when the print data [SIH, SIL]=[0, 0] is input to the decoder 216, the decoder 216 sets the logic levels of the selection signals S1, S2, and S3 in the period tp to L, L, and H levels. As a result, the selection circuit 230 supplies the drive signal VOUT including the drive waveform Cdp to the piezoelectric element 60 included in the corresponding discharge section 600 in the period tp. As a result, the ink is not discharged from the corresponding discharge section 600, and the micro-vibration BSD for vibrating the ink in the vicinity of the opening portion of the nozzle 651 included in the discharge section 600 is executed.

As described above, the selection control circuit 210 and the selection circuit 230 select or deselect the signal waveforms of the drive signals COMA, COMB, and COMC output by the drive circuits 50a, 50b, and 50c, thereby generating the drive signal VOUT and outputting the generated drive signal VOUT to the piezoelectric element 60 included in the corresponding discharge section 600.

### 4. Configuration and Operation of Drive Circuit

As described above, in the liquid discharge apparatus 1 of the present embodiment, the drive circuits 50a, 50b, and 50c supply the drive signals COMA, COMB, and COMC having a high frequency of 100 kHz or higher to a large number of the piezoelectric elements 60, that is, 3,000 or more piezoelectric elements 60, in response to the market demand for productivity improvement.

When a circuit configuration using a related art AB-class amplification circuit is applied as a drive circuit that supplies such a drive signal having a high frequency to a large number of drive elements, since the liquid discharge apparatus has a large number of drive elements such as the piezoelectric elements, a sufficient current cannot be supplied to the drive elements, as a result, the drive accuracy of the drive elements decreases, and a problem of a decrease in the discharge accuracy of liquid may occur.

In addition, when a circuit configuration using a related art D-class amplification circuit is applied as a drive circuit that supplies such a drive signal having a high frequency to a large number of drive elements, since the liquid discharge apparatus has a large number of drive elements such as the piezoelectric elements, the amount of a current flowing through a switching element configuring the D-class amplification circuit increases. As a result, the amount of heat generated in the switching element increases, and a problem of a decrease in the reliability of the drive circuit occurs. Particularly, in the D-class amplification circuit, since a signal obtained by modulating a basic drive signal that serves as the base of the drive signal is amplified by the switching operation of the switching element, when the frequency of the output drive signal is 100 kHz or higher, the drive frequency of the switching element may exceed 10 MHz, and as a result, there is a concern that the amount of heat generated in the switching element may significantly increase, and the reliability of the drive circuit may further reduce.

In response to such a problem, when the circuit configuration using the related art D-class amplification circuit is applied, a decrease in the drive frequency of the switching element included in the D-class amplification circuit reduces the switching loss in the switching element and also can reduce the amount of heat generated in the switching element. However, in a configuration in which the piezoelectric element 60 is used as the drive element as in the liquid discharge apparatus 1 according to the present embodiment, from the viewpoint of controlling the discharge amount of the ink in detail, it is necessary to finely control the displacement of the piezoelectric element 60 in the discharge period, and the voltage value of the drive signal thus significantly changes within a short time as illustrated in FIG. 4. As a result, when the frequency of the drive signal is a high frequency of 100 kHz or higher, the amount of the voltage value of the drive signal changed per 1 μs may exceed 20 V, and the period during which the voltage value of the drive signal is held constant may be shorter than 0.3 μs. Therefore, when the drive frequency of the switching element configuring the D-class amplification circuit that outputs the drive signal is decreased, a sufficient number of samples cannot be secured, the waveform accuracy of the output drive signal decreases, and a problem of a decrease in the discharge accuracy of the liquid occurs.

That is, when a circuit configuration using the related art D-class amplification circuit is applied as the drive circuit that supplies a drive signal having a high frequency to a large number of drive elements, there occurs a problem in that it becomes difficult to achieve both the reduction of the amount of heat generated from the switching element configuring the D-class amplification circuit and improvement in the waveform accuracy of the output drive signal.

In response to such a problem, in the liquid discharge apparatus 1 and the drive circuits 50a, 50b, and 50c of the present embodiment, in response to the market demand for productivity improvement, the AB-class amplification circuit is used as the circuit configuration of the drive circuits 50a, 50b, and 50c, and a transistor configuring the AB-class amplification circuit has a characteristic structure enabling a high current amplification factor to be realized. Therefore, even when the drive circuits 50a, 50b, and 50c supply the drive signals COMA, COMB, and COMC having a high frequency of 100 kHz or higher to a large number of the piezoelectric elements 60, that is, 3,000 or more piezoelectric elements 60, the amount of heat generated from the drive circuits 50a, 50b, and 50c can be reduced, furthermore, a sufficient current can be supplied to a large number of the piezoelectric elements 60, and a concern of a decrease in the waveform accuracy of the drive signals COMA, COMB, and COMC can also be reduced. As a result, the drive circuits 50a, 50b, and 50c that can supply the drive signals COMA, COMB, and COMC having a high frequency to a large number of the piezoelectric elements 60 can be realized, and as a result, the productivity in the liquid discharge apparatus 1 including the drive circuits 50a, 50b, and 50c can be improved.

Therefore, the configuration and operation of the drive circuits 50a, 50b, and 50c included in the liquid discharge apparatus 1 of the present embodiment will be described. Here, the drive circuits 50a, 50b, and 50c are different only in terms of the input signal and the output signal, and have the same configuration. Therefore, in the following description, the drive circuits 50a, 50b, and 50c will be simply referred to as the drive circuit 50 without being distinguished. At that time, in the description, a basic drive signal dO is input to the drive circuit 50 as the basic drive signals dA, dB, and dC, and the drive circuit 50 outputs the drive signal COM as the drive signals COMA, COMB, and COMC.

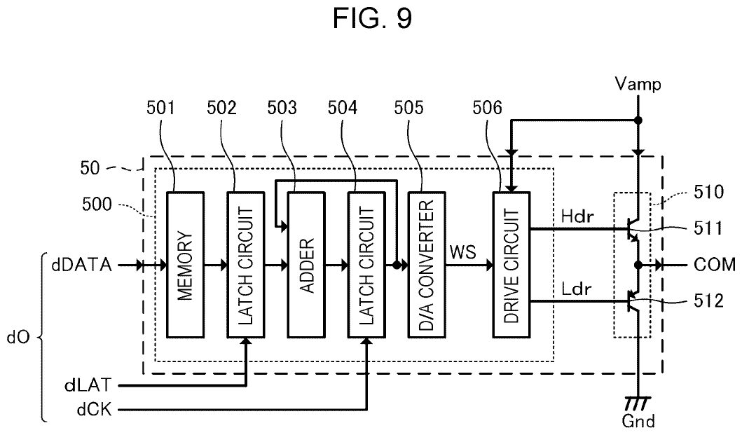

FIG. 9 is a diagram illustrating an example of the configuration of the drive circuit 50. As illustrated in FIG. 9, the drive circuit 50 includes an amplification control circuit 500 and an amplification circuit 510.

The amplification control circuit 500 includes a memory 501, a latch circuit 502, an adder 503, a latch circuit 504, a D/A converter 505, and a drive circuit 506. In addition, a voltage change amount data dDATA, a latch signal dLAT, and a clock signal dCK are input to the amplification control circuit 500 as the basic drive signal dO output by the control circuit 100.

The voltage change amount data dDATA is input to the memory 501. The memory 501 holds voltage change amount information Dv included in the input voltage change amount data dDATA. The latch signal dLAT is input to the latch circuit 502. The latch circuit 502 latches the voltage change amount information Dv held in the memory 501 at the rise of the input latch signal dLAT. In addition, the latch circuit 502 outputs the latched voltage change amount information Dv to the adder 503.

In addition to the voltage change amount information Dv output by the latch circuit 502, a signal output by a latch circuit 504 to be described below is also input to the adder 503. The adder 503 calculates and holds addition voltage change amount information obtained by adding the voltage change amount information Dv to the signal output by the latch circuit 504.

The clock signal dCK is input to the latch circuit 504. The latch circuit 504 latches the addition voltage change amount information held by the adder 503 at the rise of the clock signal dCK. In addition, the latch circuit 504 outputs the latched addition voltage change amount information to the adder 503 and the D/A converter 505. That is, the adder 503 calculates and holds new addition voltage change amount information by adding the voltage change amount information Dv latched by the latch circuit 502 to the addition voltage change amount information latched by the latch circuit 504.

The D/A converter 505 converts the addition voltage change amount information output by the latch circuit 504 into an analog signal, and outputs the analog signal to the drive circuit 506 as a drive waveform signal WS. A signal waveform obtained by amplifying the drive waveform signal WS corresponds to the signal waveform of the drive signal COM.

In addition to the drive waveform signal WS output by the D/A converter 505, a voltage signal Vamp having a predetermined voltage value input to the amplification circuit 510 is input to the drive circuit 506. The drive circuit 506 generates amplification control signals Hdr and Ldr based on the drive waveform signal WS and the voltage signal Vamp, and outputs the amplification control signals Hdr and Ldr to the amplification circuit 510. Here, the voltage value of the voltage signal Vamp is equal to or greater than the maximum value of the voltage values of the drive waveforms Adp, Bdp, and Cdp included in the drive signals COMA, COMB, and COMC.

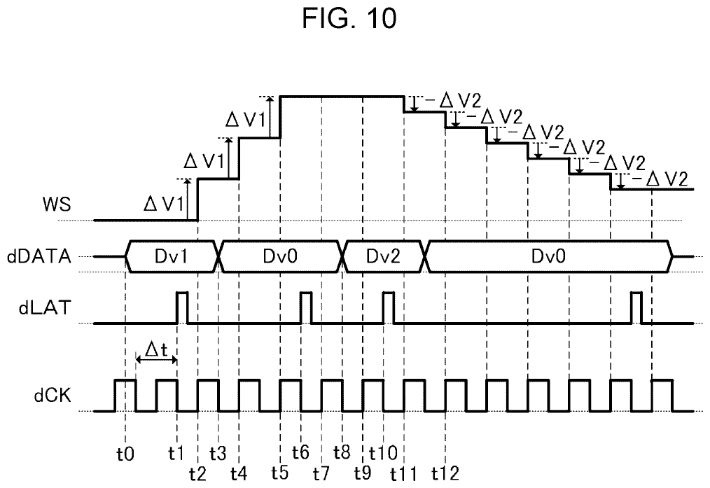

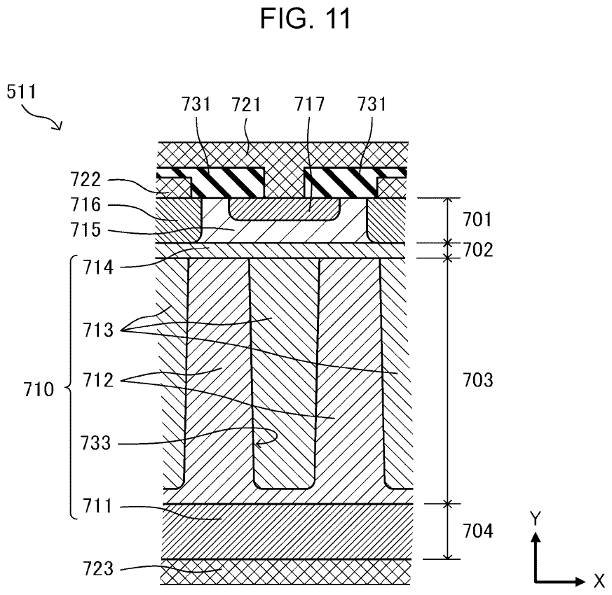

The operation of the amplification control circuit 500 configured as described above will be described. FIG. 10 is a diagram illustrating an example of the operation of the amplification control circuit 500. As illustrated in FIG. 10, at a time t0, the control circuit 100 generates the voltage change amount data dDATA including the voltage change amount information Dv1 for changing the voltage value by a voltage ΔV1 as the basic drive signal dO, and outputs the voltage change amount data dDATA to the memory 501. As a result, the voltage change amount information Dv1 is held in the memory 501.

In addition, at a time t1, the control circuit 100 sets the logic level of the latch signal dLAT as the basic drive signal dO to a high level. As a result, the voltage change amount information Dv1 held in the memory 501 is latched by the latch circuit 502. At a time t3 thereafter, the control circuit 100 outputs the voltage change amount data dDATA including voltage change amount information Dv0 for holding the voltage value constant as the basic drive signal dO to the memory 501. That is, the voltage change amount information Dv0 is held in the memory 501 instead of the voltage change amount information Dv1.

The voltage change amount information Dv1 latched by the latch circuit 502 at the time t1 is input to the adder 503. The adder 503 adds the voltage change amount information Dv1 latched by the latch circuit 502 to the addition voltage change amount information output by the latch circuit 504, and holds the addition voltage change amount information as new addition voltage change amount information.

In addition, the control circuit 100 generates the clock signal dCK that becomes an H level as the basic drive signal dO every period AT, and outputs the clock signal dCK to the latch circuit 504. In addition, at the times t2, t4, and t5, when the clock signal dCK of the H level is input to the latch circuit 504, the latch circuit 504 latches the addition voltage change amount information having the voltage value increased by the voltage ΔV1 each time the clock signal dCK of the H level is input, and outputs the addition voltage change amount information to the D/A converter 505. As a result, the D/A converter 505 generates and outputs the drive waveform signal WS having the voltage value increased by the voltage ΔV1 at the times t2, t4, and t5.

At a time t6 thereafter, the control circuit 100 sets the logic level of the latch signal dLAT as the basic drive signal dO to a high level. As a result, the voltage change amount information Dv0 for holding the voltage value held in the memory 501 constant is latched by the latch circuit 502. In addition, at a time t8 thereafter, the control circuit 100 generates the voltage change amount data dDATA including the voltage change amount information Dv2 for changing the voltage value by a voltage −ΔV2 as the basic drive signal do, and outputs the voltage change amount data dDATA to the memory 501. That is, the voltage change amount information Dv2 is held in the memory 501 instead of the voltage change amount information Dv0.

The voltage change amount information Dv0 latched by the latch circuit 502 is input to the adder 503. The adder 503 adds the voltage change amount information Dv0 latched by the latch circuit 502 to the addition voltage change amount information output by the latch circuit 504, and holds the addition voltage change amount information as new addition voltage change amount information.

In addition, at times t7 and t9, the clock signal dCK of an H level is input to the latch circuit 504. At this time, the voltage change amount information Dv0 latched by the latch circuit 502 is information for holding the voltage value constant. Therefore, the latch circuit 504 latches the addition voltage change amount information having the voltage value that does not change even when the clock signal dCK of the H level is input, and outputs the addition voltage change amount information to the D/A converter 505. As a result, the D/A converter 505 generates and outputs the drive waveform signal WS having a constant voltage value at the times t7 and t9.

In addition, at a time t10, the control circuit 100 sets the logic level of the latch signal dLAT as the basic drive signal dO to a high level. As a result, the voltage change amount information Dv2 for changing the voltage value held in the memory 501 by the voltage −ΔV2 is latched by the latch circuit 502.

The voltage change amount information Dv2 latched by the latch circuit 502 is input to the adder 503. In addition, the adder 503 adds the voltage change amount information Dv2 latched by the latch circuit 502 to the addition voltage change amount information output by the latch circuit 504, and holds the addition voltage change amount information as new addition voltage change amount information.

In addition, the control circuit 100 generates the clock signal dCK that becomes an H level as the basic drive signal dO every period AT, and outputs the clock signal dCK to the latch circuit 504. In addition, at the times t11, and t12, when the clock signal dCK of the H level is input to the latch circuit 504, the latch circuit 504 latches the addition voltage change amount information having the voltage value decreased by the voltage ΔV2 each time the clock signal dCK of the H level is input, and outputs the addition voltage change amount information to the D/A converter 505. As a result, the D/A converter 505 generates and outputs the drive waveform signal WS having the voltage value decreased by the voltage ΔV2 at the times t11 and t12.

As described above, the drive waveform signal WS having the increasing voltage value, the drive waveform signal WS having the decreasing voltage value, and the drive waveform signal WS having the constant voltage value are input to the drive circuit 506 based on the basic drive signal dO. As a result, the waveform shape of the drive waveform signal WS input to the drive circuit 506 can be arbitrarily set according to the basic drive signal dO output by the control circuit 100.

The drive circuit 506 voltage-amplifies the voltage value of the input drive waveform signal WS based on the voltage signal Vamp, thereby generating an amplification drive waveform signal. At this time, the waveform shape of the amplification drive waveform signal generated by the drive circuit 506 becomes the waveform shapes of the drive waveforms Adp, Bdp, and Cdp included in the drive signals COMA, COMB, and COMC illustrated in FIG. 4.

In addition, the drive circuit 506 generates the amplification control signal Hdr obtained by adding a bias voltage having a predetermined voltage value to the amplification drive waveform signal and the amplification control signal Ldr obtained by subtracting a bias voltage having a predetermined voltage value from the amplification drive waveform signal, and outputs the signals to the amplification circuit 510. Here, it is preferable that the voltage value of the bias voltage added to the amplification drive waveform signal is determined according to the voltage value of a base-emitter saturation voltage of a transistor 511 included in the amplification circuit 510 to be described below, and the voltage value of the bias voltage subtracted from the amplification drive waveform signal is determined according to the voltage value of a base-emitter saturation voltage of a transistor 512 included in the amplification circuit 510 to be described below. As a result, a concern of the generation of a distortion in the signal waveform of the output drive signal COM is reduced.

Here, in the liquid discharge apparatus 1 of the present embodiment, the voltage change amount data dDATA included in the basic drive signal dO input to the amplification control circuit 500 is described to be data indicating the amount of a change in the voltage value of the drive waveform signal WS every period of the clock signal dCK, but the voltage change amount data dDATA included in the basic drive signal dO may be data indicating the absolute value of the voltage value of the drive waveform signal WS every period of the clock signal dCK.

When the voltage change amount data dDATA included in the basic drive signal dO is data indicating the amount of a change in the voltage value of the drive waveform signal WS every period of the clock signal dCK, the data amount of the voltage change amount data dDATA included in the basic drive signal dO can be reduced, and as a result, the transmission rate of the voltage change amount data dDATA included in the basic drive signal dO can be increased. On the other hand, when the voltage change amount data dDATA included in the basic drive signal dO is data indicating the absolute value of the voltage value of the drive waveform signal WS every period of the clock signal dCK, the amplification control circuit 500 does not need to include the adder 503 and the latch circuit 504, and as a result, the amplification control circuit 500 can be miniaturized.

Returning to FIG. 9, the amplification circuit 510 includes the transistor 511 and the transistor 512. In the present embodiment, the transistor 511 is an NPN type bipolar transistor, and the transistor 512 is a PNP type bipolar transistor. At this time, the transistor 511 and the transistor 512 preferably configure a complementary pair.

The voltage signal Vamp is input to a collector terminal of the transistor 511. The amplification control signal Hdr is input to a base terminal of the transistor 511. An emitter terminal of the transistor 511 is electrically coupled to an emitter terminal of the transistor 512. The amplification control signal Ldr is input to a base terminal of the transistor 512. A ground potential Gnd is input to a collector terminal of the transistor 512. In addition, the amplification circuit 510 outputs a signal of a coupling point where the emitter terminal of the transistor 511 and the emitter terminal of the transistor 512 are coupled as the drive signal COM.

In such an amplification circuit 510, when the voltage value of the drive waveform signal WS increases, and the voltage value of the amplification drive waveform signal obtained by voltage-amplifying the drive waveform signal WS increases, the collector terminal and the emitter terminal of the transistor 511 are controlled to be conductive, and the emitter terminal and the collector terminal of the transistor 512 are controlled to be non-conductive. At this time, a current based on the voltage signal Vamp is supplied to the plurality of piezoelectric elements 60 coupled to a coupling point where the emitter terminal of the transistor 511 and the emitter terminal of the transistor 512 are electrically coupled, via the transistor 511. As a result, the voltage value at the coupling point where the emitter terminal of the transistor 511 and the emitter terminal of the transistor 512 are electrically coupled, which is the voltage value of the drive signal COM output by the amplification circuit 510, increases to follow the voltage value of the amplification drive waveform signal by the capacitance component of the piezoelectric element 60.

In addition, when the voltage value of the drive waveform signal WS decreases and the voltage value of the amplification drive waveform signal obtained by voltage-amplifying the drive waveform signal WS decreases, the collector terminal and the emitter terminal of the transistor 511 are controlled to be non-conductive, and the emitter terminal and the collector terminal of the transistor 512 are controlled to be conductive. At this time, electric charges stored in the plurality of piezoelectric elements 60 coupled to the coupling point where the emitter terminal of the transistor 511 and the emitter terminal of the transistor 512 are electrically coupled are released to the ground potential Gnd via the transistor 512. As a result, the voltage value at the coupling point where the emitter terminal of the transistor 511 and the emitter terminal of the transistor 512 are electrically coupled, which is the voltage value of the drive signal COM output by the amplification circuit 510, decreases to follow the voltage value of the amplification drive waveform signal.

In addition, when the voltage value of the drive waveform signal WS is constant and the voltage value of the amplification drive waveform signal obtained by voltage-amplifying the drive waveform signal WS is constant, the collector terminal and the emitter terminal of the transistor 511 are controlled to be non-conductive, and the emitter terminal and the collector terminal of the transistor 512 are controlled to be non-conductive. At this time, the voltage value at the coupling point where the emitter terminal of the transistor 511 and the emitter terminal of the transistor 512 are coupled, which is the voltage value of the drive signal COM output by the amplification circuit 510, is held by the capacitance component of the piezoelectric element 60 coupled to the coupling point. That is, the voltage value at the coupling point where the emitter terminal of the transistor 511 and the emitter terminal of the transistor 512 are electrically coupled, which is the voltage value of the drive signal COM output by the amplification circuit 510, is held at the same voltage value as the voltage value of the amplification drive waveform signal.

As described above, in the liquid discharge apparatus 1 of the present embodiment, the drive circuit 50 includes the amplification control circuit 500 and the amplification circuit 510, the amplification control circuit 500 defines the signal waveform of the drive signal COM based on the basic drive signal dO, and the amplification circuit 510 current-amplifies the signal of the signal waveform of the drive signal COM defined by the amplification control circuit 500, thereby outputting the drive signal COM enabling the plurality of piezoelectric elements 60 included in the print head 20 to be driven.

As described above, the drive circuit 50 included in the control unit 10 includes the push-pull-coupled transistor 511 and transistor 512, and has the amplification circuit 510 that current-amplifies the amplification drive waveform signal obtained by voltage-amplifying the drive waveform signal WS and the voltage value of the drive waveform signal WS based on the voltage signal Vamp, which is the signal waveform defined by the basic drive signal dO that serves as the base of the drive signal COM, and outputs the amplification drive waveform signal as the drive signal COM.

In such a drive circuit 50, when a sufficient current cannot be supplied to the plurality of piezoelectric elements 60 that are included in the print head 20 or when a sufficient electric charge cannot be released from the plurality of piezoelectric elements 60 that are included in the print head 20, the signal waveform of the output drive signal COM is distorted, and there is a concern that the drive accuracy of the piezoelectric element 60 and the discharge accuracy of the ink from the discharge section 600 may decrease. The amount of the current supplied from the drive circuit 50 to the plurality of piezoelectric elements 60 is limited by the current amplification factor of the transistor 511, and the amount of the current supplied from the plurality of piezoelectric elements 60 to the drive circuit 50, that is, the amount of electric charges released from the plurality of piezoelectric elements 60, is limited by the current amplification factor of the transistor 512. Therefore, in the drive circuit 50 of the present embodiment that outputs the drive signal COM to a large number of the piezoelectric elements 60, that is, 3000 or more piezoelectric elements 60, from the viewpoint of enhancing the waveform accuracy of the output drive signal COM, that is, the drive accuracy of the piezoelectric element 60, and the discharge accuracy of the ink from the discharge section 600, the transistors 511 and 512 have characteristic structures enabling a large current amplification factor to be realized.

An example of the structures of the transistor 511 and the transistor 512 will be described. FIG. 11 is a diagram illustrating an example of the structure of the transistor 511. In the description of the structure of the transistor 511, an X axis and a Y axis that are orthogonal to each other will be used. In addition, in the following description, the starting point side of the arrow of the X axis illustrated in the drawing may be referred to as −X side, and the tip side may be referred to as +X side. The starting point side of the arrow of the Y axis illustrated in the drawing may be referred to as −Y side, and the tip side may be referred to as +Y side.

As illustrated in FIG. 11, the transistor 511 includes layers 701 to 704 stacked from the +Y side to the −Y side along the Y axis, an emitter electrode 721, a base electrode 722, and a collector electrode 723. At this time, the layers 701 to 704 are stacked in the order of the layer 701, the layer 702, the layer 703, and the layer 704 from the +Y side to the −Y side along the Y axis. In addition, the layer 701 includes an n-type semiconductor layer 715, a p-type well 716, and an n-type well 717, the layer 702 includes a p-type channel layer 714, the layer 703 includes an n-type column layer 712 and a p-type column layer 713, and the layer 704 includes an n-type semiconductor layer 711. Here, in the following description, the n-type semiconductor layer 711 included in the layer 704, the n-type column layer 712 and the p-type column layer 713 included in the layer 703, and the p-type channel layer 714 included in the layer 702 may be collectively referred to as a semiconductor substrate 710.

The n-type semiconductor layer 711 included in the layer 704 is an n-type semiconductor layer and is positioned on the most −Y side of the semiconductor substrate 710. The n-type column layer 712 included in the layer 703 is an n-type semiconductor layer, and the p-type column layer 713 is a p-type semiconductor layer. The n-type column layer 712 is positioned on the +Y side of the layer 704, and has a plurality of trenches 733 formed from the surface on the +Y side toward the −Y side. The p-type column layer 713 is provided in each of the plurality of trenches 733 included in the n-type column layer 712. Specifically, the n-type column layer 712 is an n-type semiconductor layer formed at the +Y side of the n-type semiconductor layer 711 included in the semiconductor substrate 710, and includes a plurality of trenches 733 arranged along the X axis. The p-type column layer 713 is a p-type semiconductor layer formed by epitaxially growing a p-type crystal in the trenches 733. That is, the n-type column layer 712 and the p-type column layer 713 are positioned on the +Y side of the n-type semiconductor layer 711 and are positioned adjacent to each other and alternately in a direction along the X axis. In other words, the semiconductor substrate 710 includes a plurality of the n-type column layers 712 and a plurality of the p-type column layers 713, and the plurality of n-type column layers 712 and the plurality of p-type column layers 713 are alternately disposed in the direction along the X axis. As a result, a column region is formed in the semiconductor substrate 710. The p-type channel layer 714 included in the layer 702 is a p-type semiconductor layer, is positioned on the +Y side of the layer 703 including the column region, and is in contact with the n-type column layers 712 and the p-type column layers 713 included in the column region.

The n-type semiconductor layer 715 included in the layer 701 is an n-type semiconductor layer and is positioned on the +Y side of the layer 702. The n-type semiconductor layer 715 is an n-type semiconductor layer formed by, for example, epitaxial growth or the like. The p-type well 716 and the n-type well 717 are n-type diffusion layers formed by doping the n-type semiconductor layer 715 with an impurity. Specifically, the p-type well 716 is a p-type diffusion layer formed to reach the p-type channel layer 714 from the surface layer portion of the n-type semiconductor layer 715 on the +Y side, and the n-type well 717 is a p-type diffusion layer formed at the surface layer portion of the n-type semiconductor layer 715 on the +Y side. At this time, the p-type well 716 is provided to be in contact with the p-type channel layer 714, and the n-type well 717 is provided to be separated from the p-type channel layer 714 and the p-type well 716 by the n-type semiconductor layer 715.

Here, the impurity concentration of the n-type semiconductor layer 715 is set to be lower than the impurity concentration of the n-type column layer 712, the impurity concentration of the n-type semiconductor layer 711 and the impurity concentration of the n-type well 717 are set to be higher than the impurity concentration of the n-type column layer 712, and the impurity concentration of the p-type channel layer 714 and the impurity concentration of the p-type well 716 are set to be higher than the impurity concentration of the p-type column layer 713.

The base electrode 722 is positioned on the +Y side of the p-type well 716 included in the layer 701 and is coupled to the p-type well 716 via a contact (not illustrated). The emitter electrode 721 is positioned on the +Y side of the n-type well 717 included in the layer 701, is disposed to cover the entire transistor 511, and is coupled to the n-type well 717 via a contact (not illustrated). In addition, an insulating layer 731 is positioned between the base electrode 722 and the emitter electrode 721. The insulating layer 731 contains a silicon oxide film, a silicon nitride film, or the like. The base electrode 722 and the emitter electrode 721 are insulated from each other by the insulating layer 731. The collector electrode 723 is positioned on the −Y side of the semiconductor substrate 710 included in the layer 704 and on the −Y side of the n-type semiconductor layer 711, is disposed to cover the entire transistor 511, and is coupled to the n-type semiconductor layer 711 via a contact (not illustrated).

That is, the transistor 511 includes the layer 703 including the n-type column layer 712 having the trenches 733 and the p-type column layer 713 provided in the trenches 733, the emitter electrode 721 and the base electrode 722 positioned on the +Y side, which is one side of the layer 703 in a direction along the Y axis, the collector electrode 723 positioned on the −Y side, which is the other side of the layer 703 in the direction along the Y axis, the layer 702 which is at least partially positioned between the layer 703 and the base electrode 722 in the direction along the Y axis and includes the p-type channel layer 714, the layer 701 which includes the n-type semiconductor layer 715, the n-type well 717 provided in the n-type semiconductor layer 715, and the p-type well 716 provided in the n-type semiconductor layer 715 and positioned to be separated from the n-type well 717, and is at least partially positioned between the layer 702 and the base electrode 722 in the direction along the Y axis, and the layer 704 which is at least partially positioned between the layer 703 and the collector electrode 723 in the direction along the Y axis and includes the n-type semiconductor layer 711.

In other words, the transistor 511 includes the emitter electrode 721 that functions as an emitter terminal, the base electrode 722 that functions as a base terminal, the collector electrode 723 that functions as a collector terminal, the layer 703 including the n-type column layer 712 having the trenches 733 and the p-type column layer 713 provided in the trenches 733, the layer 702 including the p-type channel layer 714, and the layer 701 including the n-type semiconductor layer 715, the n-type well 717, and the p-type well 716 positioned to be separated from the n-type well 717, the layer 703 is disposed above the collector electrode 723, the layer 702 is disposed above the layer 703, the layer 701 is disposed above the layer 702, the emitter electrode 721 is disposed above the n-type well 717, the base electrode 722 is disposed above the p-type well 716, the transistor 511 further includes the layer 704 including the n-type semiconductor layer 711, and the layer 704 is disposed between the collector electrode 723 and the layer 703. Here, the fact that “a configuration B is disposed above a configuration A” means that the configuration B is positioned at least on the +Y side of the configuration A. That is, the fact that “the configuration B is disposed above the configuration A” means that the configuration B may be positioned on and adjacent to the configuration A along the Y axis, or a different configuration may be provided between the configuration A and the configuration B along the Y axis.

The operation of the transistor 511 configured as described above will be described.

The transistor 511 is turned on by supplying a positive voltage to the collector electrode 723 so that the potential on the collector side becomes positive with respect to the potential on the source side and supplying a positive voltage to the base electrode 722.

Specifically, when a positive voltage is supplied to the collector electrode 723 so that the potential on the collector side becomes positive with respect to the potential on the source side, and a positive voltage is supplied to the base electrode 722, holes are poured from the p-type well 716 into the n-type well 717 and are also poured from the p-type well 716 into the p-type channel layer 714. The holes poured into the p-type channel layer 714 flow into the p-type column layer 713 and the n-type column layer 712 via the p-type channel layer 714. As a result, at least the upper structure of the column region including the p-type column layer 713 and the n-type column layer 712 is reduced in resistance by the conductivity modulation. At this time, electrons are poured from the n-type well 717 into the p-type channel layer 714. In addition, the electrons poured into the p-type channel layer 714 flow into the low-resistance p-type column layer 713 and n-type column layer 712 via the p-type channel layer 714 and reach the collector electrode 723. As a result, a current flows between the emitter electrode 721 and the collector electrode 723, and the transistor 511 is turned on.

On the other hand, the transistor 511 is turned off when a positive voltage is not supplied to the base electrode 722. When a positive voltage is not supplied to the base electrode 722 and a positive voltage is supplied to the collector electrode 723, a depletion layer spreads toward both the p-type column layer 713 and the n-type column layer 712 from each of a plurality of pn junctions formed between the p-type column layer 713 and the n-type column layer 712. As a result, the column region including the p-type column layer 713 and the n-type column layer 712 is depleted at a low electric field intensity, and the withstand voltage of the transistor 511 can be increased. At this time, the current between the emitter electrode 721 and the collector electrode 723 is blocked, and the transistor 511 is turned off.

In the transistor 511 configured as described above, since a reverse bias is held in the column region including the p-type column layer 713 and the n-type column layer 712 in the off state, the spread of the depletion layer toward the p-type channel layer 714 is small, and the p-type channel layer 714 can be thinned. Therefore, in the on state, the electron pouring efficiency from the emitter side to the collector side can be increased. Furthermore, in the on state, the holes are efficiently poured from the base electrode 722 to the n-type column layer 712 via the p-type column layer 713. As a result, a conductivity modulation phenomenon occurs, the on-resistance of the transistor 511 can be reduced, and the current amplification factor increases.

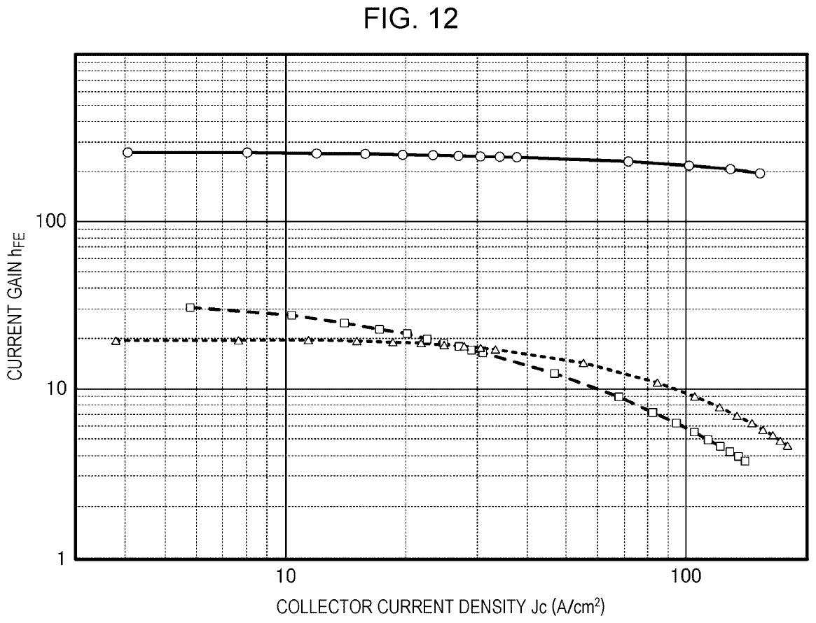

FIG. 12 is a diagram illustrating the comparison results of an example of the current amplification factor of an npn type bipolar transistor having a structure in the related art and an example of the current amplification factor of the transistor 511 of the present embodiment. FIG. 12 illustrates the comparison results when a voltage of 2 V is supplied between the collector and the emitter. In addition, in the comparison results illustrated in FIG. 12, the current density of the collector current is illustrated on the horizontal axis, and the current amplification factor is illustrated on the vertical axis.

As illustrated in FIG. 12, in the transistor 511 of the present embodiment, a current amplification factor of 10 times or more can be obtained as compared with the npn type bipolar transistor with a structure in the related art.

Here, the transistor 511 and the transistor 512 have the same configuration except that one is an NPN type bipolar transistor and the other is a PNP type bipolar transistor.

That is, although not illustrated, the transistor 512 includes a semiconductor substrate corresponding to the semiconductor substrate 710, a p-type semiconductor layer instead of the n-type semiconductor layer 715, an n-type well instead of the p-type well 716, a p-type well instead of the n-type well 717, an emitter electrode corresponding to the emitter electrode 721, a base electrode corresponding to the base electrode 722, and a collector electrode corresponding to the collector electrode 723, and the semiconductor substrate includes a p-type semiconductor layer instead of the n-type semiconductor layer 711, a p-type column layer instead of the n-type column layer 712, an n-type column layer instead of the p-type column layer 713, and an n-type channel layer instead of the p-type channel layer 714.

In addition, the transistor 512 includes a layer including a p-type column layer instead of the n-type column layer 712 having the trenches and an n-type column layer instead of the p-type column layer 713 provided in the trenches, an emitter electrode and a base electrode positioned on the +Y side, which is one side of the layer including the p-type column layer and the n-type column layer in the direction along the Y axis, a collector electrode positioned on the −Y side, which is the other side of the layer including the p-type column layer and the n-type column layer in the direction along the Y axis, a layer which is at least partially positioned between the layer including the p-type column layer and the n-type column layer and the base electrode in the direction along the Y axis and includes an n-type channel layer instead of the p-type channel layer 714, a layer which includes a p-type semiconductor layer instead of the n-type semiconductor layer 715, a p-type well instead of the n-type well 717 provided in the p-type semiconductor layer, and a p-type well instead of the n-type well 717 positioned to be separated from the p-type well provided in the p-type semiconductor layer and is at least partially positioned between the layer including the n-type channel layer instead of the p-type channel layer 714 and the base electrode in the direction along the Y axis, and a layer which is at least partially positioned between the layer including the p-type column layer and the n-type column layer and the collector electrode in the direction along the Y axis and includes a p-type semiconductor layer instead of the n-type semiconductor layer 711, whereby a large current amplification factor can also be obtained in the transistor 512.

Here, the drive signal COM is an example of the drive signal, at least one of the control unit 10 and the drive circuit 50 included in the control unit 10 is an example of the print head drive circuit, the amplification circuit 510 included in the drive circuit 50 is an example of the amplification circuit, the transistor 511 is an example of the first transistor, and the transistor 512 is an example of the second transistor. In addition, the layer 703 is an example of the first layer, the layer 702 is an example of the second layer, the layer 701 is an example of the third layer, and the layer 704 is an example of the fourth layer. In addition, the n-type is an example of the first conductive type, the p-type is an example of the second conductive type, the trench 733 is an example of the trench, the n-type column layer 712 is an example of the first semiconductor region, the p-type column layer 713 is an example of the second semiconductor region, the p-type channel layer 714 is an example of the third semiconductor region, the n-type semiconductor layer 715 is an example of the fourth semiconductor region, the n-type well 717 is an example of the fifth semiconductor region, the p-type well 716 is an example of the sixth semiconductor region, and the n-type semiconductor layer 711 is an example of the seventh semiconductor region. The emitter electrode 721 is an example of the first conductor, the base electrode 722 is an example of the second conductor, and the collector electrode 723 is an example of the third conductor.

### 5. Operational Effect

In the liquid discharge apparatus 1 of the present embodiment configured as described above, the drive circuit 50 that outputs the drive signal COM is configured by the AB-class amplification circuit including the push-pull-coupled transistor 511 and the transistor 512, whereby the switching loss in the transistor 511 and the transistor 512 can be reduced compared to the drive circuit 50 configured using the D-class amplification circuit. As a result, from the viewpoint of improving the productivity of the liquid discharge apparatus 1, even when the drive circuit 50 outputs the drive signal COM having a high frequency, a concern of an increase in the amount of heat generated in the drive circuit 50, that is, the amount of heat generated in the transistors 511 and 512, is reduced.

Furthermore, in the liquid discharge apparatus 1 of the present embodiment configured as described above, the transistor 511 includes the emitter electrode 721 that functions as an emitter terminal, the base electrode 722 that functions as a base terminal, the collector electrode 723 that functions as a collector terminal, the layer 703 including the n-type column layer 712 having the trenches 733 and the p-type column layer 713 provided in the trenches 733, the layer 702 including the p-type channel layer 714, and the layer 701 including the n-type semiconductor layer 715, the n-type well 717, and the p-type well 716 positioned to be separated from the n-type well 717, the layer 703 is disposed above the collector electrode 723, the layer 702 is disposed above the layer 703, the layer 701 is disposed above the layer 702, the emitter electrode 721 is disposed above the n-type well 717, and the base electrode 722 is disposed above the p-type well 716, whereby the current amplification factor of the transistor 511 can be increased. As a result, the amount of a current that can be output by the transistor 511 increases. Therefore, from the viewpoint of improving the productivity of the liquid discharge apparatus 1, even when the print head 20 has a large number of the piezoelectric elements 60 and a large number of the piezoelectric elements 60 are driven by the drive signal COM output by the drive circuit 50, a sufficient current can be supplied to the piezoelectric element 60. Therefore, a concern of a decrease in the drive accuracy of the piezoelectric element 60 is reduced.

That is, in the liquid discharge apparatus 1 of the present embodiment, since the drive circuit 50 enables the drive signal COM having a high frequency to be stably supplied to a large number of the piezoelectric elements 60 included in the print head 20, the productivity of the liquid discharge apparatus 1 can be enhanced.

In addition, in the liquid discharge apparatus 1 of the present embodiment configured as described above, since the transistor 512 has the same configuration as the transistor 511, even when the print head 20 has a large number of the piezoelectric elements 60 and a large number of the piezoelectric elements 60 are driven by the drive signal COM output by the drive circuit 50, a sufficient current can be more stably supplied to the piezoelectric element 60. Therefore, a concern of a decrease in the drive accuracy of the piezoelectric element 60 is further reduced.

In addition, in the liquid discharge apparatus 1 of the present embodiment, since the drive circuit 50 enables the drive signal COM having a high frequency to be stably supplied to a large number of the piezoelectric elements 60 included in the print head 20, even when the print head 20 includes the 3,000 or more piezoelectric elements 60 and the drive circuit 50 supplies the drive signal COM to the 3,000 or more piezoelectric elements 60, or the drive circuit 50 outputs the drive signal COM having a frequency of 100 kHz or higher, and the drive circuit 50 includes a period in which the voltage value of the output drive signal COM changes by 20 V or more per microsecond, or the drive signal COM includes a period of shorter than 0.3 μs in which the voltage value is constant, the drive circuit 50 enables the drive signal COM having a high frequency of 100 kHz or higher to be stably supplied to the 3,000 or more piezoelectric elements 60 included in the print head 20. As a result, the productivity of the liquid discharge apparatus 1 can be enhanced.

Hitherto, the embodiments and the modification examples have been described. However, the present disclosure is not limited to the embodiments, and can be implemented in various aspects within the scope not departing from the concept of the present disclosure. For example, the above-described embodiments can also be appropriately combined with each other.

The present disclosure includes substantially the same configurations (for example, configurations having the same functions, methods, and results, or configurations having the same objects and effects) as the configurations described in the embodiments. In addition, the present disclosure includes configurations in which non-essential parts of the configuration described in the embodiments are replaced. In addition, the present disclosure includes configurations that achieve the same operational effects or configurations that can achieve the same objects as those of the configurations described in the embodiments. In addition, the present disclosure includes configurations in which a known technology is added to the configurations described in the embodiments.

The following contents are derived from the above-described embodiments.

An aspect of the liquid discharge apparatus includes a print head that discharges a liquid in response to a drive signal; and a print head drive circuit that outputs the drive signal, in which the print head drive circuit includes an amplification circuit that outputs the drive signal amplified by a first transistor and a second transistor, the first transistor includes a first conductor that functions as an emitter electrode, a second conductor that functions as a base electrode, a third conductor that functions as a collector electrode, a first layer that includes a first semiconductor region of a first conductive type having a trench and a second semiconductor region of a second conductive type provided in the trench, a second layer that includes a third semiconductor region of the second conductive type, and a third layer that includes a fourth semiconductor region of the first conductive type, a fifth semiconductor region of the first conductive type, and a sixth semiconductor region of the second conductive type positioned to be separated from the fifth semiconductor region, the first layer is disposed above the third conductor, the second layer is disposed above the first layer, the third layer is disposed above the second layer, the first conductor is disposed above the fifth semiconductor region, and the second conductor is disposed above the sixth semiconductor region.

In the liquid discharge apparatus, the print head drive circuit includes the amplification circuit that has the push-pull-coupled first transistor and second transistor, amplifies the basic drive signal that serves as the base of the drive signal, and outputs the amplified basic drive signal as a drive signal, whereby even when a drive signal having a high frequency is output, a concern of a significant increase in the drive frequencies of the first transistor and the second transistor is reduced. As a result, the generation of heat in the print head drive circuit including the first transistor and the second transistor is reduced.

In addition, in the liquid discharge apparatus, the first transistor included in the amplification circuit includes the first conductor that functions as an emitter electrode, the second conductor that functions as a base electrode, the third conductor that functions as a collector electrode, the first layer that includes the first semiconductor region of the first conductive type having the trenches and the second semiconductor region of the second conductive type provided in the trenches, the second layer that includes the third semiconductor region of the second conductive type, and the third layer that includes the fourth semiconductor region of the first conductive type, the fifth semiconductor region of the first conductive type, and the sixth semiconductor region of the second conductive type positioned to be separated from the fifth semiconductor region, the first layer is disposed above the third conductor, the second layer is disposed above the first layer, the third layer is disposed above the second layer, the first conductor is disposed above the fifth semiconductor region, and the second conductor is disposed above the sixth semiconductor region, whereby the current amplification factor of the first transistor can be increased. As a result, even when a large number of drive elements are driven in the drive signal COM, a sufficient current for driving the drive elements can be supplied.

As described above, in the liquid discharge apparatus, since the drive signal having a high frequency can be stably supplied to a large number of the drive elements, the productivity of the liquid discharge apparatus can be enhanced.

In an aspect of the liquid discharge apparatus, the impurity concentration of the fourth semiconductor region may be lower than the impurity concentration of the first semiconductor region, the impurity concentration of the fifth semiconductor region may be higher than the impurity concentration of the first semiconductor region, and the impurity concentration of the third semiconductor region and the impurity concentration of the sixth semiconductor region may be higher than the impurity concentration of the second semiconductor region.

In an aspect of the liquid discharge apparatus, the first transistor may further include the fourth layer that includes the seventh semiconductor region of the first conductive type, the fourth layer may be disposed between the third conductor and the first layer, and the impurity concentration of the seventh semiconductor region may be higher than the impurity concentration of the first semiconductor region.

In an aspect of the liquid discharge apparatus, the print head may include 3000 or more piezoelectric elements, and the 3000 or more piezoelectric elements may be driven by the drive signal.

In the liquid discharge apparatus, since the drive signal having a high frequency can be stably supplied to a large number of the drive elements, even when the drive signal is supplied to the 3000 or more piezoelectric elements, the stable operation of the liquid discharge apparatus and the print head drive circuit can be realized.

In an aspect of the liquid discharge apparatus, the frequency of the drive signal may be 100 kHz or higher.

In the liquid discharge apparatus, since the drive signal having a high frequency can be stably supplied to a large number of the drive elements, even when the frequency of the drive signal is 100 kHz or higher, the stable operation of the liquid discharge apparatus and the print head drive circuit can be realized.

In an aspect of the liquid discharge apparatus, the drive signal may include a period in which the voltage value changes by 20 V or more per microsecond.

In the liquid discharge apparatus, since the drive signal having a high frequency can be stably supplied to a large number of the drive elements, even when the drive signal includes a period in which the voltage value changes by 20 V or more per microsecond, the stable operation of the liquid discharge apparatus and the print head drive circuit can be realized.

In an aspect of the liquid discharge apparatus, the drive signal may include a period of shorter than 0.3 μs in which the voltage value is constant.

In the liquid discharge apparatus, since the drive signal having a high frequency can be stably supplied to a large number of the drive elements, even when the drive signal includes a period of shorter than 0.3 μs in which the voltage value is constant, the stable operation of the liquid discharge apparatus and the print head drive circuit can be realized.

In an aspect of the liquid discharge apparatus, the amplification circuit may be an AB-class amplification circuit.

In the liquid discharge apparatus, the amount of heat generated in the amplification circuit can be reduced, and even when the drive signal is supplied to a large number of the drive elements, and a large current is thus output, a sufficient current can be supplied to the drive elements, and a concern of a decrease in the waveform accuracy of the drive signal can be reduced.

An aspect of a print head drive circuit is a print head drive circuit that outputs a drive signal to a print head that discharges a liquid in response to the drive signal, the print head drive circuit including an amplification circuit that outputs the drive signal amplified by a first transistor and a second transistor, in which the first transistor includes a first conductor that functions as an emitter electrode, a second conductor that functions as a base electrode, a third conductor that functions as a collector electrode, a first layer that includes a first semiconductor region of a first conductive type having a trench and a second semiconductor region of a second conductive type provided in the trench, a second layer that includes a third semiconductor region of the second conductive type, and a third layer that includes a fourth semiconductor region of the first conductive type, a fifth semiconductor region of the first conductive type, and a sixth semiconductor region of the second conductive type positioned to be separated from the fifth semiconductor region, the first layer is disposed above the third conductor, the second layer is disposed above the first layer, the third layer is disposed above the second layer, the first conductor is disposed above the fifth semiconductor region, and the second conductor is disposed above the sixth semiconductor region.

The print head drive circuit includes the amplification circuit that has the push-pull-coupled first transistor and second transistor, amplifies the basic drive signal that serves as the base of the drive signal, and outputs the amplified basic drive signal as a drive signal, whereby even when a drive signal having a high frequency is output, a concern of a significant increase in the drive frequencies of the first transistor and the second transistor is reduced. As a result, the generation of heat in the print head drive circuit including the first transistor and the second transistor is reduced.

In addition, in the print head drive circuit, the first transistor included in the amplification circuit includes the first conductor that functions as an emitter electrode, the second conductor that functions as a base electrode, the third conductor that functions as a collector electrode, the first layer that includes the first semiconductor region of the first conductive type having the trenches and the second semiconductor region of the second conductive type provided in the trenches, the second layer that includes the third semiconductor region of the second conductive type, and the third layer that includes the fourth semiconductor region of the first conductive type, the fifth semiconductor region of the first conductive type, and the sixth semiconductor region of the second conductive type positioned to be separated from the fifth semiconductor region, the first layer is disposed above the third conductor, the second layer is disposed above the first layer, the third layer is disposed above the second layer, the first conductor is disposed above the fifth semiconductor region, and the second conductor is disposed above the sixth semiconductor region, whereby the current amplification factor of the first transistor can be increased. As a result, even when a large number of drive elements are driven in the drive signal COM, a sufficient current for driving the drive elements can be supplied.

As described above, in the print head drive circuit, since the drive signal having a high frequency can be stably supplied to a large number of the drive elements, the productivity of the liquid discharge apparatus in which the print head drive circuit is mounted can be enhanced.

In an aspect of the print head drive circuit, the impurity concentration of the fourth semiconductor region may be lower than the impurity concentration of the first semiconductor region, the impurity concentration of the fifth semiconductor region may be higher than the impurity concentration of the first semiconductor region, and the impurity concentration of the third semiconductor region and the impurity concentration of the sixth semiconductor region may be higher than the impurity concentration of the second semiconductor region.

In an aspect of the print head drive circuit, the first transistor may further include the fourth layer that includes the seventh semiconductor region of the first conductive type, the fourth layer may be disposed between the third conductor and the first layer, and the impurity concentration of the seventh semiconductor region may be higher than the impurity concentration of the first semiconductor region.

In an aspect of the print head drive circuit, the print head may include 3000 or more piezoelectric elements, and the 3000 or more piezoelectric elements may be driven by the drive signal.

In the print head drive circuit, since the drive signal having a high frequency can be stably supplied to a large number of the drive elements, even when the drive signal is supplied to the 3000 or more piezoelectric elements, the stable operation of the liquid discharge apparatus and the print head drive circuit can be realized.

In an aspect of the print head drive circuit, the frequency of the drive signal may be 100 kHz or higher.

In the print head drive circuit, since the drive signal having a high frequency can be stably supplied to a large number of the drive elements, even when the frequency of the drive signal is 100 kHz or higher, the stable operation of the liquid discharge apparatus and the print head drive circuit can be realized.

In an aspect of the print head drive circuit, the drive signal may include a period in which the voltage value changes by 20 V or more per microsecond.

In the print head drive circuit, since the drive signal having a high frequency can be stably supplied to a large number of the drive elements, even when the drive signal includes a period in which the voltage value changes by 20 V or more per microsecond, the stable operation of the liquid discharge apparatus and the print head drive circuit can be realized.

In an aspect of the print head drive circuit, the drive signal may include a period of shorter than 0.3 μs in which the voltage value is constant.

In the print head drive circuit, since the drive signal having a high frequency can be stably supplied to a large number of the drive elements, even when the drive signal includes a period of shorter than 0.3 μs in which the voltage value is constant, the stable operation of the liquid discharge apparatus and the print head drive circuit can be realized.

In an aspect of the print head drive circuit, the amplification circuit may be an AB-class amplification circuit.

In the print head drive circuit, the amount of heat generated in the amplification circuit can be reduced, and even when the drive signal is supplied to a large number of the drive elements, and a large current is thus output, a sufficient current can be supplied to the drive elements, and a concern of a decrease in the waveform accuracy of the drive signal can be reduced.

What is claimed is:

1. A liquid discharge apparatus comprising:
a print head that discharges a liquid in response to a drive signal; and
a print head drive circuit that outputs the drive signal, wherein
the print head drive circuit includes an amplification circuit that outputs the drive signal amplified by a first transistor and a second transistor,
the first transistor includes
a first conductor that functions as an emitter electrode,
a second conductor that functions as a base electrode,
a third conductor that functions as a collector electrode,
a first layer that includes a first semiconductor region of a first conductive type having a trench and a second semiconductor region of a second conductive type provided in the trench,
a second layer that includes a third semiconductor region of the second conductive type, and
a third layer that includes a fourth semiconductor region of the first conductive type, a fifth semiconductor region of the first conductive type, and a sixth semiconductor region of the second conductive type positioned to be separated from the fifth semiconductor region,
the first layer is disposed above the third conductor,
the second layer is disposed above the first layer,
the third layer is disposed above the second layer,
the first conductor is disposed above the fifth semiconductor region, and
the second conductor is disposed above the sixth semiconductor region.

2. The liquid discharge apparatus according to claim 1, wherein
an impurity concentration of the fourth semiconductor region is lower than an impurity concentration of the first semiconductor region,
an impurity concentration of the fifth semiconductor region is higher than the impurity concentration of the first semiconductor region, and
an impurity concentration of the third semiconductor region and an impurity concentration of the sixth semiconductor region are higher than an impurity concentration of the second semiconductor region.

3. The liquid discharge apparatus according to claim 1, wherein
the first transistor further includes a fourth layer that includes a seventh semiconductor region of the first conductive type,
the fourth layer is disposed between the third conductor and the first layer, and
an impurity concentration of the seventh semiconductor region is higher than an impurity concentration of the first semiconductor region.

4. The liquid discharge apparatus according to claim 1, wherein
the print head includes 3000 or more piezoelectric elements, and
the 3000 or more piezoelectric elements are driven by the drive signal.

5. The liquid discharge apparatus according to claim 1, wherein
a frequency of the drive signal is 100 kHz or higher.

6. The liquid discharge apparatus according to claim 1, wherein
the drive signal includes a period in which a voltage value changes by 20 V or more per microsecond.

7. The liquid discharge apparatus according to claim 1, wherein
the drive signal includes a period of shorter than 0.3 μs in which a voltage value is constant.

8. The liquid discharge apparatus according to claim 1, wherein
the amplification circuit is an AB-class amplification circuit.

9. A print head drive circuit that outputs a drive signal to a print head that discharges a liquid in response to the drive signal, the print head drive circuit comprising:
an amplification circuit that outputs the drive signal amplified by a first transistor and a second transistor, wherein
the first transistor includes
a first conductor that functions as an emitter electrode,
a second conductor that functions as a base electrode,
a third conductor that functions as a collector electrode,
a first layer that includes a first semiconductor region of a first conductive type having a trench and a second semiconductor region of a second conductive type provided in the trench,
a second layer that includes a third semiconductor region of the second conductive type, and
a third layer that includes a fourth semiconductor region of the first conductive type, a fifth semiconductor region of the first conductive type, and a sixth semiconductor region of the second conductive type positioned to be separated from the fifth semiconductor region,
the first layer is disposed above the third conductor,
the second layer is disposed above the first layer,
the third layer is disposed above the second layer,
the first conductor is disposed above the fifth semiconductor region, and
the second conductor is disposed above the sixth semiconductor region.

10. The print head drive circuit according to claim 9, wherein
an impurity concentration of the fourth semiconductor region is lower than an impurity concentration of the first semiconductor region,
an impurity concentration of the fifth semiconductor region is higher than the impurity concentration of the first semiconductor region, and
an impurity concentration of the third semiconductor region and an impurity concentration of the sixth semiconductor region are higher than an impurity concentration of the second semiconductor region.

11. The print head drive circuit according to claim 9, wherein
the first transistor further includes a fourth layer that includes a seventh semiconductor region of the first conductive type,
the fourth layer is disposed between the third conductor and the first layer, and
an impurity concentration of the seventh semiconductor region is higher than an impurity concentration of the first semiconductor region.

12. The print head drive circuit according to claim 9, wherein
the print head includes 3000 or more piezoelectric elements, and
the 3000 or more piezoelectric elements are driven by the drive signal.

13. The print head drive circuit according to claim 9, wherein
a frequency of the drive signal is 100 kHz or higher.

14. The print head drive circuit according to claim 9, wherein
the drive signal includes a period in which a voltage value changes by 20 V or more per microsecond.

15. The print head drive circuit according to claim 9, wherein
the drive signal includes a period of shorter than 0.3 μs in which a voltage value is constant.

16. The print head drive circuit according to claim 9, wherein
the amplification circuit is an AB-class amplification circuit.
